(19) United States
(12) Patent Application Publication
(10) Pub. No.: US 2026/0251968 A1
(43) Pub. Date: Aug. 27, 2026

(54) LITHOGRAPHY SYSTEM HAVING THREE-DIMENSIONAL SCAFFOLD PELLICLE STRUCTURE AND RELATED METHODS

(71) Applicant: Taiwan Semiconductor Manufacturing Company, Limited., Hsin-Chu (TW)

(72) Inventors: Pei-Hsun TSAI, Hsinchu County (TW); Yun-Yue LIN, Hsinchu City (TW)

(21) Appl. No.: 19/061,194

(22) Filed: Feb. 24, 2025

(51) Int. Cl. G03F 1/62; B82Y 20/00; B82Y 40/00; G03F 7/00; H01L 21/263

(52) U.S. Cl. CPC G03F 1/62; G03F 7/70033; G03F 7/70983; B82Y 20/00; B82Y 40/00; H10P 34/40

(57) ABSTRACT

A method is provided. The method includes: generating light by a plasma of a light source of a semiconductor processing tool; generating patterned light by a mask assembly, the patterned light including the light reflected by a pattern of the mask assembly; during generating the patterned light, protecting the mask assembly by a pellicle assembly including a pellicle membrane, the pellicle membrane including a nanotube-based scaffold structure having nanotubes bound together by a capping layer; and performing a semiconductor process on a semiconductor wafer by the patterned light.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more semiconductor fabrication processes are performed to form semiconductor devices on, in, and/or from a semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic view of a system, in accordance with some embodiments.

FIG. 1B illustrates a schematic view of a system, in accordance with some embodiments.

FIG. 1C illustrates a schematic view of a light source of the system of FIG. 1B, in accordance with some embodiments.

FIGS. 2A, 2B, 2C, 2D, 2E, 2F, and 2G illustrate schematic views of a method of forming a pellicle assembly, in accordance with some embodiments.

FIG. 2H illustrates a schematic view of the pellicle assembly, in accordance with some embodiments.

FIGS. 3A, 3B, 3C, 3D, 3E, 3F, 3G, 3H, 3I, 3J and 3K illustrate schematic views of methods of forming a pellicle assembly, in accordance with some embodiments.

FIGS. 4A, 4B, 4C, 4D, 4E, 4F, 4G, 4H, and 4I illustrate schematic views of a method of forming a pellicle membrane, in accordance with some embodiments.

FIG. 5 illustrates a schematic view of a pellicle monitoring system, in accordance with some embodiments.

FIG. 6 is a flow diagram illustrating a method, in accordance with some embodiments.

FIG. 7 is a flow diagram illustrating a method, in accordance with some embodiments.

FIG. 8 illustrates an example computer-readable medium wherein processor-executable instructions configured to embody one or more of the provisions set forth herein may be comprised, according to some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

With progress in advanced semiconductor process nodes, high volume manufacturing implements extreme ultraviolet (EUV) photolithography that is beneficial to pattern a photosensitive resist layer having nanoscale features. EUV light having exposure energy in excess of 600 Watts (W) is generated and directed to a reflective mask or reticle having a pattern therein that is carried by the reflected light and transferred to the resist layer. The mask is positioned in a near-vacuum chamber, which is beneficial to reduce presence of particles. The particles can include tin debris formed during generation of the EUV light, hydrocarbons present due to seals in the chamber, and the like. When a particle settles on the mask, the particle may obscure or change the pattern carried by the reflected light, resulting in defects in the patterned resist layer.

A pellicle can be mounted to the mask, which is beneficial to catch and or block the particles via a thin membrane that is transparent or substantially transparent in the EUV spectrum. The pellicle is subjected to long exposure to EUV light, environmental stresses and repeated rapid acceleration and deceleration across tens of thousands of moves. Silicon-based pellicles are increasingly insufficient with respect to mechanical and thermal durability, at least due to recrystallization properties at temperatures below 600° C. For example, silicon-based materials face challenges in high EUV power exposure environments, in which the membrane surface heats up rapidly to temperatures in excess of 800° C. due to emissivity of silicon being less than 0.02. Membrane strength is limited by thickness limitations and film coverage integrity.

In embodiments of the disclosure, a membrane of the pellicle includes at least two layers of carbon nanotubes (CNTs) embedded in a binding layer. Formation of the membrane can include layer-by-layer stacking of a nanowire layer, followed by a binding layer, followed by a nanowire layer, followed by a binding layer. Thermal treatment is performed to sinter or fuse the binding layers together. CNTs can be a core element onto which the binding layers are coated to form a good core-shell coating structure. The binding layer(s) can include one or more elements that are beneficial to improve optical and mechanical properties of the membrane. The element(s) can be Mo, Si, B, C, N, P, O, alloys thereof, or the like. The nanostructure can be amorphous or crystalline. The binding layer can also be a metal oxide or metal oxynitride having high EUV transmission and exposure durability. Embodiments of the binding layer can include Ru, Nb, Al, Mo, alloys thereof, and the like. Dopants can be included in a deposition process that forms the binding layer. Embodiments of the dopants can include titanium, vanadium, and the like. Inclusion of the dopant(s) can result in formation of incomplete interface bonds between grains of the binding layer, which can reduce surface tension of the material, which improves EUV tolerance of the material of the binding layer.

Including a thin film binding layer and a nanowire material such as CNT is beneficial for the pellicle to have improved strength, improved durability in an EUV exposure environment, and improved transmission in the DUV and EUV spectrums. Namely, pellicles having high strength with long exposure lifetime are provided. The pellicles have high environment stability and lifetime that can exceed over 40,000 wafer moves. The pellicles are beneficial to both EUV and deep ultraviolet (DUV) optical properties, which results in increased wafer throughput.

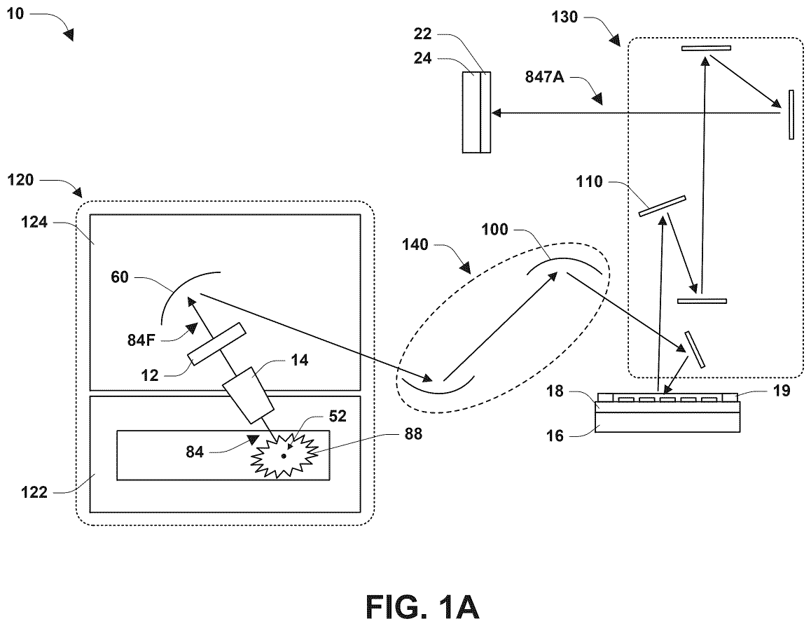

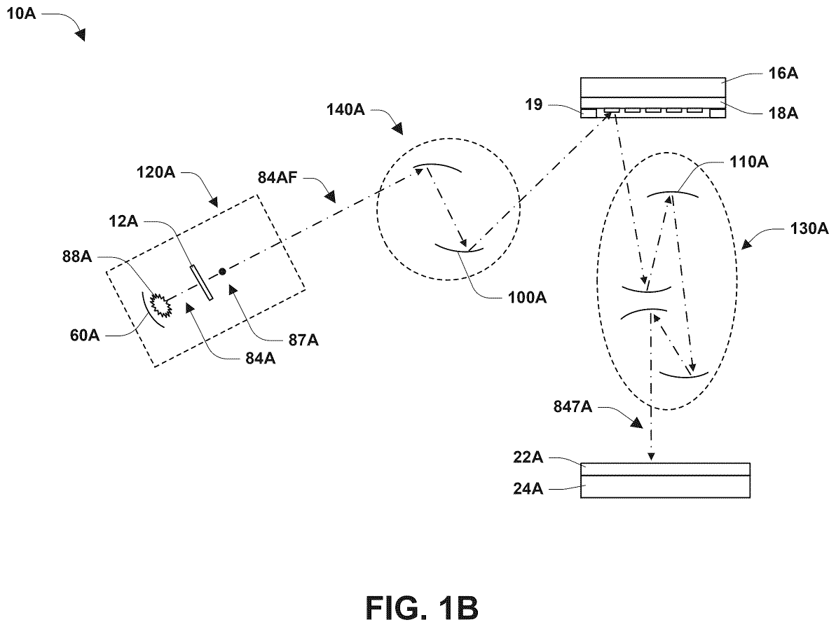

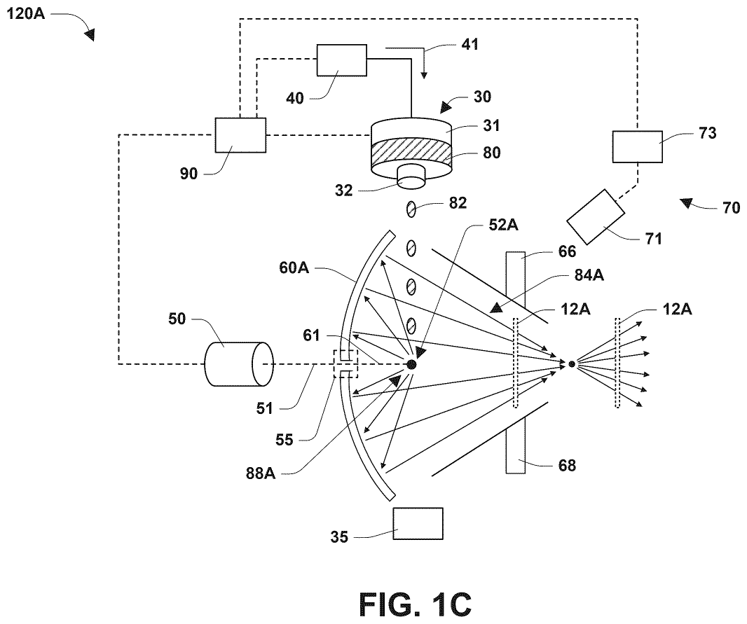

FIG. 1A illustrates a schematic view of a system 10, in accordance with some embodiments. In some embodiments, the system 10 is a lithography system, such as a lithography exposure system, and can be referred to as the lithography system 10 or the lithography exposure system 10. In some embodiments, the system 10 is a semiconductor processing tool, and can be referred to as the semiconductor processing tool 10.

In some embodiments, the system 10 is an extreme ultraviolet (EUV) lithography system designed to expose a resist layer by EUV radiation. The system 10 includes a light source 120, an illuminator 140, a mask stage 16, a projection optics module (or projection optics box (POB)) 130 and a substrate stage 24, in accordance with some embodiments. The elements of the system 10 can be added to or omitted, and the disclosure should not be limited by the embodiment. Some elements of the system 10 may be rearranged in other embodiments. For example, position of a collector mirror 60 relative to a lighting point 52 and the illuminator 140 may be different than that depicted in FIG. 1A. An embodiment including a collector mirror 60A arranged differently than the collector mirror 60 is depicted in, and described with reference to, FIGS. 1B and 1C. The collector mirrors 60, 60A may each be referred to as a collector.

The light source 120 is configured to generate light radiation 84 (or “first light 84”) having a wavelength ranging between about 1 nm and about 100 nm in certain embodiments. In one particular example, the light source 120 generates an EUV radiation 84 with a wavelength centered at about or substantially at 13.5 nm. Accordingly, the light source 120 is also referred to as an EUV radiation source. However, it should be appreciated that the light source 120 should not be limited to emitting EUV radiation 84. The light source 120 can be utilized to perform any high-intensity photon emission from excited target fuel.

The light source 120 includes a first chamber 122 and a second chamber 124 that are in optical communication with each other via a transport tube 14. The first chamber 122 may be operated at a first pressure, and the second chamber 124 may be operated at a second pressure that is different than the first pressure.

In some embodiments, the light source 120 includes a droplet generator that delivers a target fuel to a zone of excitation at which at least one laser pulse from a laser generator hits the droplets. In an embodiment, the target fuel includes tin (Sn). The laser generator is configured to generate at least one laser pulse to allow the conversion of the droplets into plasma 88. In some embodiments, the laser generator is configured to produce a laser pulse to the lighting point 52 to convert the droplets to plasma 88 which generates EUV radiation 84. The laser pulse can be directed through a window (or lens), and irradiate droplets at the lighting point 52. In some embodiments, the lighting point 52 is in the first chamber 122.

The plasma 88 emits EUV radiation 84, which is collected by the collector 60 and directed toward the illuminator 140. The collector 60 reflects and focuses the EUV radiation 84 for the lithography processes performed through an exposure tool, such as the system 10. In some embodiments, the collector 60 is in the second chamber 124.

In some embodiments, the laser generator is a carbon dioxide (CO2) laser source. In some embodiments, the laser generator is used to generate the laser pulse with single wavelength. The laser pulse can be transmitted through an optic assembly for focusing and determining incident angle of the laser pulse. In some embodiments, the laser pulse has a spot size of about 200-300 μm, such as 225 μm. The laser pulse is generated to have certain driving power to meet wafer production targets, such as a throughput of 125 wafers per hour (WPH), though greater WPH may be achieved. In some embodiments, the laser pulse is equipped with about 23 kW driving power. In various embodiments, the driving power of the laser pulse is at least 20 kW, such as 27 kW.

In various embodiments, the illuminator 140 includes various refractive optic components, such as a single lens or a lens system having multiple reflectors or mirrors 100, for example lenses (zone plates) or alternatively reflective optics (for EUV lithography exposure system), such as a single mirror or a mirror system having multiple mirrors in order to direct light from the light source 120 onto the mask stage 16, particularly to a mask 18 secured on the mask stage 16. In the present embodiment where the light source 120 generates light in the EUV wavelength range, reflective optics are employed. In some embodiments, the illuminator 140 includes at least three lenses.

The mask stage 16 is configured to secure the mask 18. In some embodiments, the mask stage 16 includes an electrostatic chuck (e-chuck) to secure the mask 18. This is because gas molecules absorb EUV radiation and the lithography exposure system for the EUV lithography patterning is maintained in a vacuum environment to avoid EUV intensity loss. In the present disclosure, the terms mask, photomask, and reticle are used interchangeably. In the present embodiment, the mask 18 is a reflective mask. One exemplary structure of the mask 18 includes a substrate with a suitable material, such as a low thermal expansion material (LTEM) or fused quartz. In various examples, the LTEM includes TiO₂ doped SiO₂, or other suitable materials with low thermal expansion. The mask 18 includes a reflective multilayer deposited on the substrate. The mask 18 has a pellicle assembly 19 mounted thereto, which is beneficial to reduce settling of particles on the mask 18.

The projection optics module (or projection optics box (POB)) 130 is configured for imaging the pattern of the mask 18 on to a semiconductor wafer secured on a substrate stage of the system 10. In some embodiments, the POB 130 has refractive optics (such as for a UV lithography exposure system) or alternatively reflective optics (such as for an EUV lithography exposure system) in various embodiments, e.g., optics 110. The light directed from the mask 18, carrying the image of the pattern defined on the mask, is collected by the POB 130. The illuminator 140 and the POB 130 are collectively referred to as an optical module of the system 10. In some embodiments, the POB 130 includes at least five reflective optics.

In some embodiments, the semiconductor wafer 22 is made of silicon or other semiconductor materials. Alternatively, or additionally, the semiconductor wafer 22 may include other elementary semiconductor materials such as germanium (Ge). In some embodiments, the semiconductor wafer 22 is made of a compound semiconductor such as silicon carbide (SiC), gallium arsenic (GaAs), indium arsenide (InAs), or indium phosphide (InP). In some embodiments, the semiconductor wafer 22 is made of an alloy semiconductor such as silicon germanium (SiGe), silicon germanium carbide (SiGeC), gallium arsenic phosphide (GaAsP), or gallium indium phosphide (GaInP). In some other embodiments, the semiconductor wafer 22 may be a silicon-on-insulator (SOI) or a germanium-on-insulator (GOI) substrate.

In some embodiments, the system 10 is operable to perform one or more semiconductor manufacturing process operations on the semiconductor wafer 22. The semiconductor wafer (or simply “the wafer”) 22 comprises at least one of a substrate, a photomask, a semiconductor device, a dielectric layer, an epitaxial layer, a silicon-on-insulator (SOI) structure, a semiconductor layer, a conductive material layer, a die, etc. The semiconductor wafer 22 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. The semiconductor wafer 22 comprises at least one of monocrystalline silicon, crystalline silicon with a <100> crystallographic orientation, crystalline silicon with a <110> crystallographic orientation, crystalline silicon with a <111> crystallographic orientation or other suitable material. Other structures and/or configurations of the semiconductor wafer 22 are within the scope of the present disclosure.

The semiconductor wafer 22 may have various device elements. Examples of device elements that are formed in the semiconductor wafer 22 include transistors (e.g., metal oxide semiconductor field effect transistors (MOSFET), complementary metal oxide semiconductor (CMOS) transistors, bipolar junction transistors (BJT), high voltage transistors, high-frequency transistors, p-channel and/or n-channel field-effect transistors (PFETs/NFETs), etc.), diodes, and/or other applicable elements. Various processes are performed to form the device elements, such as deposition, etching, implantation, photolithography, annealing, and/or other suitable processes. In some embodiments, the semiconductor wafer 22 is coated with a resist layer sensitive to the EUV radiation. Various components including those described above are integrated together and are operable to perform lithography processes.

The system 10 may include other modules or be integrated with (or be coupled with) other modules, such as a cleaning module designed to provide hydrogen gas to the light source 120. The hydrogen gas helps reduce contamination in the light source 120.

In some embodiments, the system 10 includes a filter assembly 12. The filter assembly 12 is positioned in the second chamber 124. In operation, when light radiation 84 that includes in-band light (e.g., EUV light) and OOB light is incident on the filter assembly 12, the filter assembly 12 can remove the OOB light while allowing the in-band light (e.g., EUV light) to pass through. Removing the OOB light is beneficial because heat from the OOB light, which can reside in the 100 nm-800 nm and >1000 nm ranges, can degrade following mirrors, such as the collector mirror 60. Over time, a filter element of the filter assembly 12 can degrade, for example, due to oxidization or holes being formed therethrough. The oxidization can result in reduction in brightness of the in-band light. The holes in the filter element can result in passage of the OOB light to the following mirror(s), which can result in heating of the mirror(s) that can damage the mirror(s). For example, the heating can increase formation of oxides, hydrocarbons or both on the surface of the affected mirror(s), such as the collector mirror 60. The oxidization or increase of hydrocarbon film on the collector mirror 60 or the mirrors 100, 110 of the illuminator 140 or the POB 130, can reduce brightness of the in-band light, which reduces throughput of the system 10. In operation, filtered light 84F including the in-band light is generated by removing the OOB light from the first light 84 by the filter assembly 12 that is positioned between the plasma 88 and the collector mirror 60.

FIG. 1B illustrates a schematic view of a system 10A, in accordance with some embodiments. FIG. 1C illustrates a schematic view of a light source 120A of the system 10A of FIG. 1B, in accordance with some embodiments. In some embodiments, the system 10A is a lithography system, such as a lithography exposure system, and can be referred to as the lithography system 10A or the lithography exposure system 10A. In some embodiments, the system 10A is a semiconductor processing tool, and can be referred to as the semiconductor processing tool 10A.

FIG. 1B illustrates a schematic and diagrammatic view of the lithography exposure system 10A, in accordance with some embodiments. In some embodiments, the lithography exposure system 10A is an extreme ultraviolet (EUV) lithography system designed to expose a resist layer by EUV radiation, and may also be referred to as the EUV system 10A. The lithography exposure system 10A includes a light source 120A, an illuminator 140A, a mask stage 16A, a projection optics module (or projection optics box (POB)) 130A and a substrate stage 24A, in accordance with some embodiments. The elements of the lithography exposure system 10A can be added to or omitted, and the disclosure should not be limited by the embodiment.

The light source 120A is configured to generate light radiation 84A having a wavelength ranging between about 1 nm and about 100 nm in certain embodiments. In one particular example, the light source 120A generates an EUV radiation 84A with a wavelength centered at about 13.5 nm. Accordingly, the light source 120A is also referred to as an EUV radiation source. However, it should be appreciated that the light source 120A should not be limited to emitting EUV radiation 84A. The light source 120A can be utilized to perform any high-intensity photon emission from excited target fuel.

In various embodiments, the illuminator 140A includes various refractive optic components, such as a single lens or a lens system having multiple reflectors or mirrors 100A, for example lenses (zone plates) or alternatively reflective optics (for EUV lithography exposure system), such as a single mirror or a mirror system having multiple mirrors in order to direct light from the light source 120A onto the mask stage 16A, particularly to a mask 18A secured on the mask stage 16A. In the present embodiment where the light source 120A generates light in the EUV wavelength range, reflective optics are employed. In some embodiments, the illuminator 140 includes at least two lenses.

The mask stage 16A is configured to secure the mask 18A. In some embodiments, the mask stage 16A includes an electrostatic chuck (e-chuck) to secure the mask 18A. This is because gas molecules absorb EUV radiation and the lithography exposure system for the EUV lithography patterning is maintained in a vacuum environment to avoid EUV intensity loss. In the present disclosure, the terms mask, photomask, and reticle are used interchangeably. In the present embodiment, the mask 18A is a reflective mask. One exemplary structure of the mask 18A includes a substrate with a suitable material, such as a low thermal expansion material (LTEM) or fused quartz. In various examples, the LTEM includes TiO₂ doped SiO₂, or other suitable materials with low thermal expansion. The mask 18A includes a reflective multilayer deposited on the substrate. The mask 18A has a pellicle assembly 19 mounted thereto, which is beneficial to reduce settling of particles on the mask 18A.

The projection optics module (or projection optics box (POB)) 130A is configured for imaging the pattern of the mask 18A on to a semiconductor wafer 22A secured on the substrate stage 24A of the lithography exposure system 10A. In some embodiments, the POB 130A has refractive optics (such as for a UV lithography exposure system) or alternatively reflective optics (such as for an EUV lithography exposure system) in various embodiments, e.g., optics 110A. The light directed from the mask 18A, carrying the image of the pattern defined on the mask, is collected by the POB 130A. The illuminator 140A and the POB 130A are collectively referred to as an optical module of the lithography exposure system 10A. In some embodiments, the POB 130A includes at least five reflective optics.

In some embodiments, the semiconductor wafer 22A is made of silicon or other semiconductor materials. Alternatively or additionally, the semiconductor wafer 22A may include other elementary semiconductor materials such as germanium (Ge). In some embodiments, the semiconductor wafer 22A is made of a compound semiconductor such as silicon carbide (SiC), gallium arsenic (GaAs), indium arsenide (InAs), or indium phosphide (InP). In some embodiments, the semiconductor wafer 22 is made of an alloy semiconductor such as silicon germanium (SiGe), silicon germanium carbide (SiGeC), gallium arsenic phosphide (GaAsP), or gallium indium phosphide (GaInP). In some other embodiments, the semiconductor wafer 22A may be a silicon-on-insulator (SOI) or a germanium-on-insulator (GOI) substrate.

In some embodiments, the system 10A is operable to perform one or more semiconductor manufacturing process operations on the semiconductor wafer 22A. The semiconductor wafer 22A (or simply “the wafer 22A”) comprises at least one of a substrate, a photomask, a semiconductor device, a dielectric layer, an epitaxial layer, a silicon-on-insulator (SOI) structure, a semiconductor layer, a conductive material layer, a die, etc. The semiconductor wafer 22A comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. The semiconductor wafer 22A comprises at least one of monocrystalline silicon, crystalline silicon with a <100> crystallographic orientation, crystalline silicon with a <110> crystallographic orientation, crystalline silicon with a <111> crystallographic orientation or other suitable material. Other structures and/or configurations of the semiconductor wafer 22A are within the scope of the present disclosure.

The semiconductor wafer 22A may have various device elements. Examples of device elements that are formed in the semiconductor wafer 22A include transistors (e.g., metal oxide semiconductor field effect transistors (MOSFET), complementary metal oxide semiconductor (CMOS) transistors, bipolar junction transistors (BJT), high voltage transistors, high-frequency transistors, p-channel and/or n-channel field-effect transistors (PFETs/NFETs), etc.), diodes, and/or other applicable elements. Various processes are performed to form the device elements, such as deposition, etching, implantation, photolithography, annealing, and/or other suitable processes. In some embodiments, the semiconductor wafer 22A is coated with a resist layer sensitive to the EUV radiation. Various components including those described above are integrated together and are operable to perform lithography processes.

The system 10A includes a filter assembly 12A. The filter assembly 12A is positioned in between plasma 88A and a focal point 87A. In some embodiments, the focal point 87A is positioned between the plasma 88A and the filter assembly 12A. Namely, the filter assembly 12A may be positioned before or after the focal point 87A along an optical path from the collector 60A to the substrate stage 24A.

In operation, when light radiation 84A emitted by the plasma 88A that includes in-band light (e.g., EUV light) and OOB light is incident on the filter assembly 12A, the filter assembly 12A can remove the OOB light while allowing the in-band light (e.g., EUV light) to pass through. Removing the OOB light is beneficial because heat from the OOB light, which can reside in the 100 nm-800 nm and >1000 nm ranges, can degrade following mirrors, such as the mirror(s) 100A. Over time, a filter element of the filter assembly 12A can degrade, for example, due to oxidization or holes being formed therethrough. The oxidization can result in reduction in brightness of the in-band light. The holes in the filter element can result in passage of the OOB light to the following mirror(s), which can result in heating of the mirror(s) that can damage the mirror(s). For example, the heating can increase formation of oxides, hydrocarbons or both on the surface of the affected mirror(s), such as the mirror(s) 100A. The oxidization or increase of hydrocarbon film on the mirrors 100A, 110A of the illuminator 140A or the POB 130A, can reduce brightness of the in-band light, which reduces throughput of the system 10A.

The lithography exposure system 10A may include other modules or be integrated with (or be coupled with) other modules, such as a cleaning module designed to provide hydrogen gas to the light source 120A. The hydrogen gas helps reduce contamination in the light source 120A. Further description of the light source 120A is provided with reference to FIG. 1C.

In FIG. 1C, the light source 120A is shown in a diagrammatical view, in accordance with various embodiments. In some embodiments, the light source 120A employs a dual-pulse laser produced plasma (LPP) mechanism to generate the plasma 88A and further generate EUV light radiation 84A from the plasma 88A. The light source 120A includes a droplet generator 30, a droplet receptacle 35, a laser generator 50, a laser produced plasma (LPP) collector 60A (also referred to as “the collector 60A”), a monitoring device 70 and a controller 90. Some or all of the above-mentioned elements of the light source 120A may be held under vacuum. It should be appreciated that the elements of the light source 120A can be added to or omitted, and should not be limited by the embodiment.

The droplet generator 30 is configured to generate a plurality of droplets 82, which may be elongated, of a target fuel 80 to a zone of excitation at which at least one laser pulse 51 from the laser generator 50 hits the droplets 82. In an embodiment, the target fuel 80 includes tin (Sn). In an embodiment, the droplets 82 may be formed with an elliptical shape. In an embodiment, the droplets 82 are generated at a rate of about 50 kilohertz (kHz) and are introduced into the zone of excitation in the light source 120A at a speed of about 70 meters per second (m/s). Other material can also be used for the target fuel 80, for example, a tin containing liquid material such as eutectic alloy containing tin, lithium (Li), and xenon (Xe). The target fuel 80 in the droplet generator 30 may be in a liquid phase.

The laser generator 50 is configured to generate at least one laser pulse to allow the conversion of the droplets 82 into the plasma 88A. In some embodiments, the laser generator 50 is configured to produce a laser pulse 51 to the lighting point 52A to convert the droplets 82 to the plasma 88A which generates the light radiation 84A. The laser pulse 51 is directed through window (or lens) 55, and irradiates droplets 82 at the lighting point 52A. The window 55 is formed in the collector 60A and adopts a suitable material substantially transparent to the laser pulse 51. The droplet receptacle 35 catches and collects unused droplets 82 and/or scattered material of the droplets 82 resulting from the laser pulse 51 striking the droplets 82.

The plasma emits light radiation 84A, which is collected by the collector 60A and directed toward the focal point 87A. The collector 60A further reflects and focuses the light radiation 84A for the lithography processes performed through an exposure tool. In some embodiments, the collector 60A has an optical axis 61 which is parallel to the direction of the laser pulse 51. In some embodiments, the collector 60A includes at least two collector sections that are arranged concentrically and physically separated from each other. The collector 60A may include a vessel wall 65 having first and second pumps 66, 68 attached thereto. In some embodiments, the first and second pumps 66, 68 include scrubbers configured to remove particulates and/or gases from the collector 60A. The first and second pumps 66, 68 may be collectively referred to as “the pumps 66, 68” herein.

In some embodiments, the laser generator 50 is a carbon dioxide (CO2) laser source. In some embodiments, the laser generator 50 is used to generate the laser pulse 51 with single wavelength. The laser pulse 51 is transmitted through an optic assembly for focusing and determining incident angle of the laser pulse 51. In some embodiments, the laser pulse 51 has a spot size of about 200-300 μm, such as 225 μm. The laser pulse 51 is generated to have certain driving power to meet wafer production targets, such as a throughput of 125 wafers per hour (WPH), though greater WPH may be achieved. In some embodiments, the laser pulse 51 is equipped with about 23 kW driving power. In various embodiments, the driving power of the laser pulse 51 is at least 20 kW, such as 27 kW.

The monitoring device 70 is configured to monitor one or more conditions in the light source 120A so as to produce data for controlling configurable parameters of the light source 120A. In some embodiments, the monitoring device 70 includes a metrology tool 71 and an analyzer 73. In cases where the metrology tool 71 is configured to monitor condition of the droplets 82 supplied by the droplet generator 30, the metrology tool may include an image sensor, such as a charge coupled device (CCD), complementary metal oxide semiconductor (CMOS) sensor, or the like. The metrology tool 71 produces a monitoring image including image or video of the droplets 82 and transmits the monitoring image to the analyzer 73. In cases where the metrology tool 71 is configured to detect energy or intensity of the light radiation 84A produced by the droplet 82 in the light source 120, the metrology tool 71 may include a number of energy sensors. The energy sensors may be any suitable sensors that are able to observe and measure energy of electromagnetic radiation in the ultraviolet region. In some embodiments, the metrology tool 71 can include, supplement, or replace the first sensor 74A.

The analyzer 73 is configured to analyze signals produced by the metrology tool 71 and outputs a detection signal to the controller 90 according to an analyzing result. For example, the analyzer 73 includes an image analyzer. The analyzer 73 receives the data associated with the images transmitted from the metrology tool 71 and performs an image analysis process on the images of the droplets 82 in the excitation zone. Afterwards, the analyzer 73 sends data related to the analysis to the controller 90. The analysis may include a flow path error or a position error.

In some embodiments, two or more metrology tools 71 are used to monitor different conditions of the light source 120. One is configured to monitor condition of the droplets 82 supplied by the droplet generator 30, and the other is configured to detect energy or intensity of the EUV light 84 produced by the droplet 82 in the light source 120. In some embodiments, the metrology tool 71 is a final focus module (FFM) and positioned in the laser generator 50 to detect light reflected from the droplet 82.

The controller 90 is configured to control one or more elements of the light source 120A. In some embodiments, the controller 90 is configured to drive the droplet generator 30 to generate the droplets 82. In addition, the controller 90 is configured to drive the laser generator 50 to fire the laser pulse 51. The generation of the laser pulse 51 may be controlled to be associated with the generation of droplets 82 by the controller 90 so as to make the laser pulse 51 hit each droplet 82 in sequence.

In some embodiments, the droplet generator 30 includes a reservoir 31 and a nozzle assembly 32. The reservoir 31 is configured for holding the target fuel 80. In some embodiments, one gas line 41 is connected to the reservoir 31 for introducing pumping gas, such as argon, from a gas source 40 into the reservoir 31. By controlling the gas flow in the gas line 41, the pressure in the reservoir 31 can be manipulated. For example, when gas is continuously supplied into the reservoir 31 via the gas line 41, the pressure in the reservoir 31 increases. As a result, the target fuel 80 in the reservoir 31 can be forced out of the reservoir 31 in the form of droplets 82.

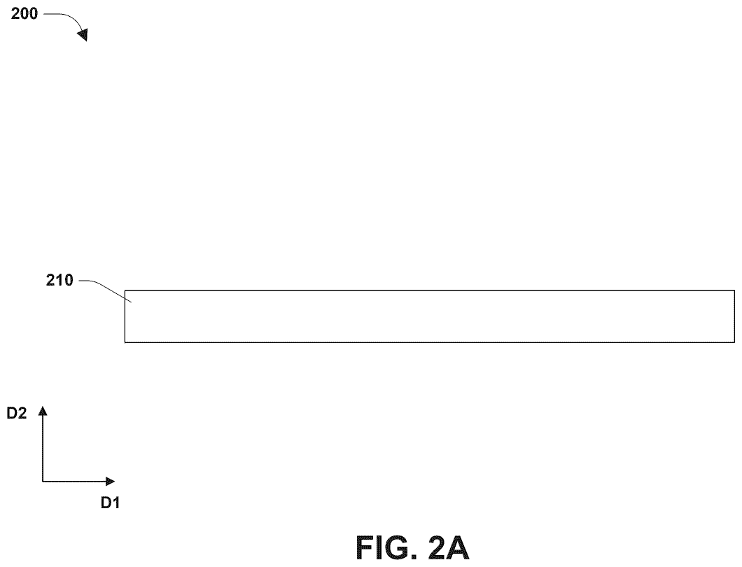

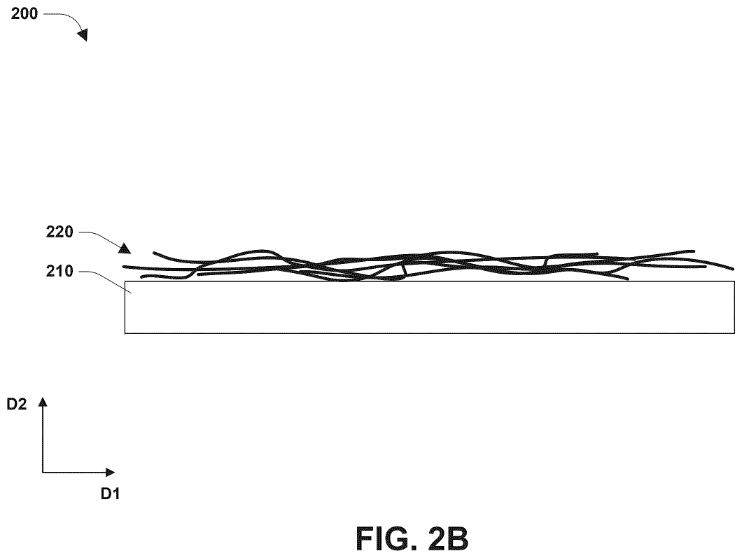

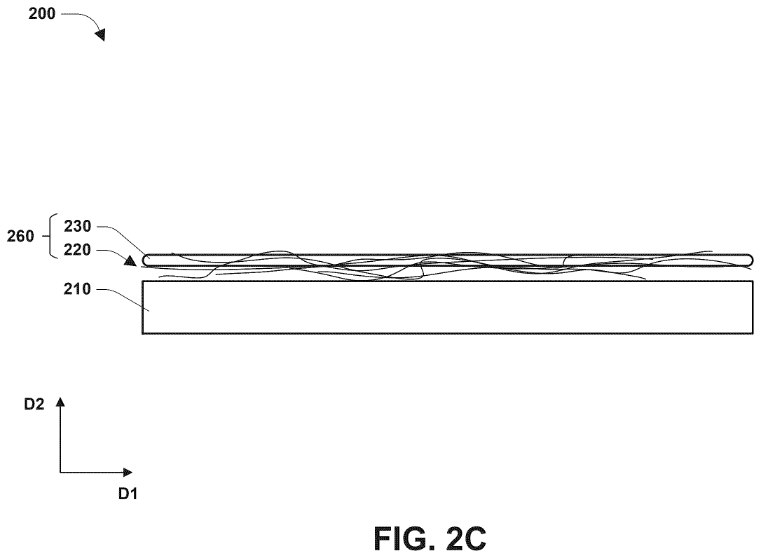

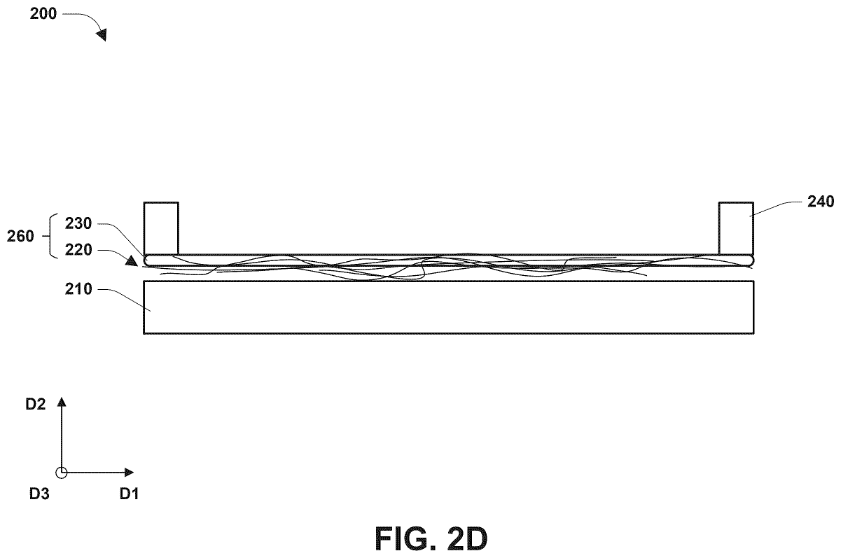

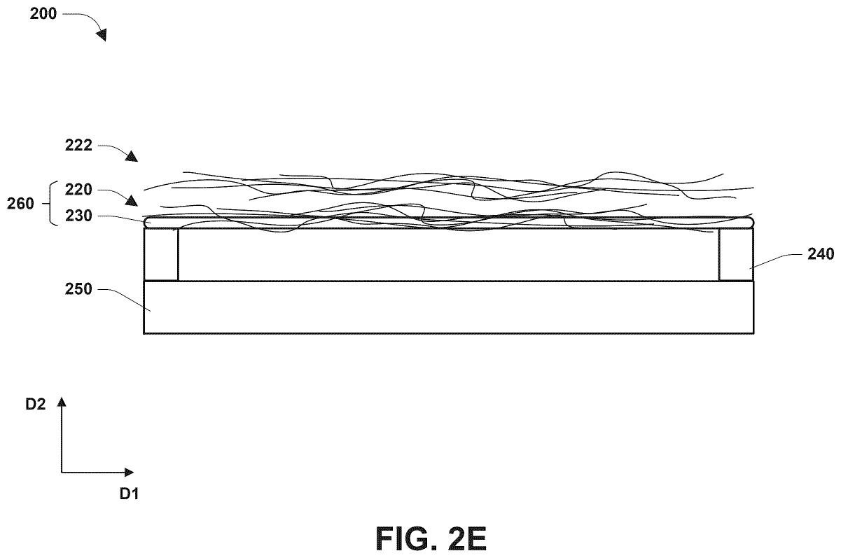

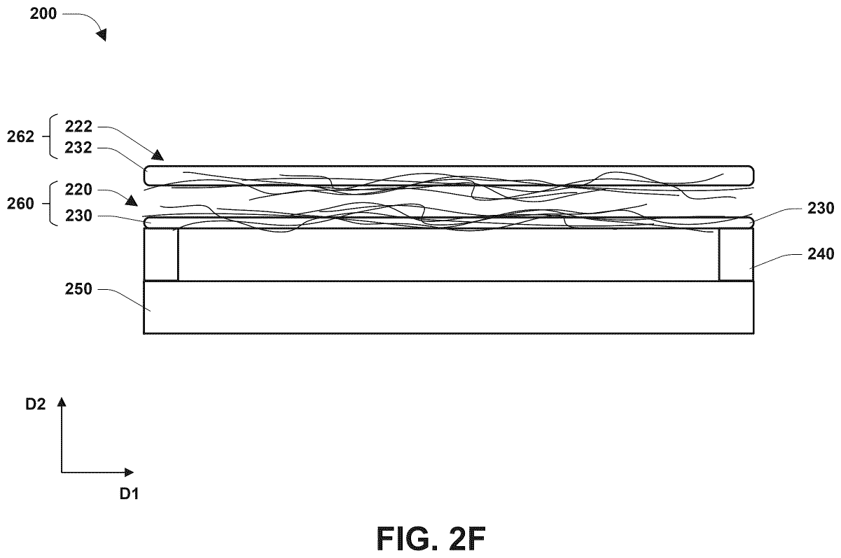

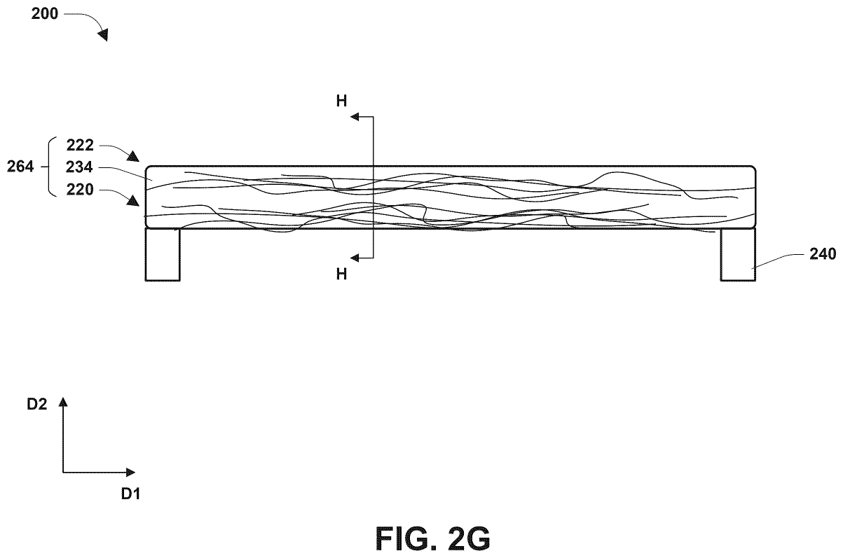

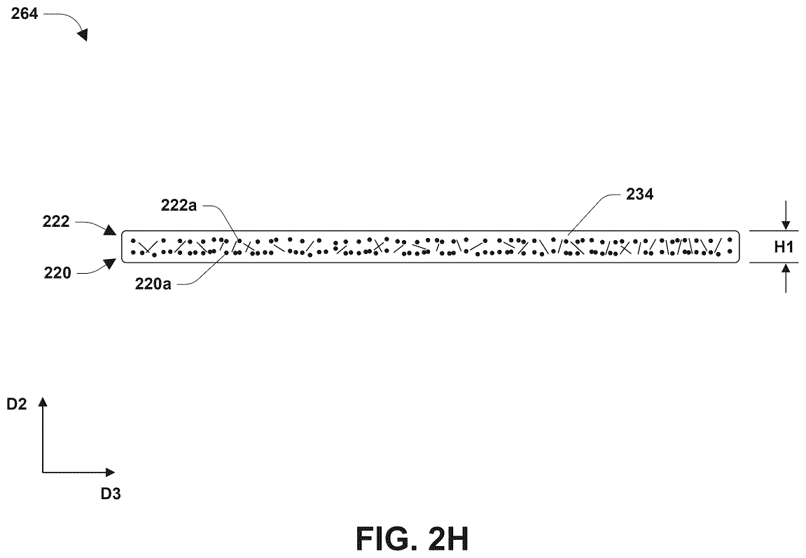

FIGS. 2A, 2B, 2C, 2D, 2E, 2F, and 2G illustrate schematic views of a method of forming a pellicle assembly 200, in accordance with some embodiments. FIG. 2H illustrates a schematic view of the pellicle assembly 200, in accordance with some embodiments.

In FIG. 2A, a substrate 210 is provided. In some embodiments, the substrate 210 is or includes filter paper and can be referred to as the filter paper 210. The filter paper 210 is operable to be used as a substrate for low-density nanotube deposition by gaseous deposition. In some embodiments, the nanotubes can be or include carbon nanotubes (CNT), boron-doped carbon nanotubes (BCNT), boron nitride nanotubes (BNNT), and the like. In some embodiments, the nanotubes have temperature stability in a range of about 600° C. to about 1000° C. In some embodiments, a thin layer (e.g., thickness of about 5 nm) of the nanotubes has transparency to EUV light in a range of about 95% to about 98%. In some embodiments, thermal conductivity of the nanotubes is in a range of about 200 Watts per meter per Kelvin (W/m·K) to about 800 W/m·K. In some embodiments, strength (e.g., Young's modulus) of the nanotubes is in a range of about 800 to about 1200. The methods described with reference to FIGS. 2A-4I are described in the context of CNTs for convenience and simplicity of description, but the methods are not limited to CNTs and may be performed to form structures that include BCNTs, BNNTs, and the like.

Properties of the filter paper 210 may be selected to be beneficial to one or more aspects of the deposition process. Material composition of the filter paper 210 may include high-purity cellulose or glass fiber that is beneficial to withstand optional high temperatures and chemical environment of the deposition process. Glass fiber, for example, may be selected for improved thermal resistance during a drying process. The filter paper 210 may have a structure that allows for gas flow while providing a surface where CNTs can settle. For example, the filter paper 210 may have structure that balances open structure (for gas permeability) with surface area (for CNT deposition). In some embodiments, the filter paper 210 includes pores that have size selected to allow passage of a carrier gas while trapping CNTs. For example, the pores may be small enough to capture the CNTs efficiently but not so small as to cause excessive pressure drop or clogging. In some embodiments, the filter paper 210 can have a gradient in pore size or a layered structure including a coarse layer allowing initial capture of larger CNT agglomerates and a finer layer for trapping smaller or individual CNTs. In some embodiments, surface of the filter paper 210 may be treated to have a charge that attracts CNTs, which can be beneficial to improve deposition efficiency, for example, when the CNTs are charged in the gas mixture. In some embodiments, the filter paper 210 has mechanical strength sufficient to withstand the flow of the carrier gas without deforming or tearing, which could lead to inconsistent CNT deposition. Other surface treatments or coatings may also be included, for example, to improve adhesion of the CNTs to the filter paper 210, improve uniformity of a layer of CNTs formed by the deposition process, or the like.

In FIG. 2B, a first nanotube layer 220 is formed by depositing CNTs on the filter paper 210 by the deposition process. In some embodiments, the deposition process includes depositing carbon nanotubes (CNTs) on the filter paper 210 using a carrier gas. In some embodiments, the CNTs are initially dispersed in a liquid medium (e.g., ethanol or water) with the aid of surfactants or sonication to prevent aggregation, which is beneficial for the CNTs to be well-dispersed prior to aerosolization. Then, the CNT suspension can be aerosolized using one or more operations, which can include atomization, electrospray, or the like. Atomization can include spraying the suspension into a carrier gas to create an aerosol. Electrospray can include using an electric field to disperse the CNTs into fine droplets. In some embodiments, a carrier gas is introduced. In some embodiments, the carrier gas is or includes an inert gas, such as argon, nitrogen or the like. The carrier gas can carry the CNTs towards the filter paper 210. Selection of the carrier gas can improve deposition efficiency and behavior of CNTs due to differences in gas properties, such as density or viscosity. The CNT-laden gas stream is directed towards the filter paper 210. Flow rate, pressure, and temperature of the carrier gas can be selected to improve yield of the deposition process. The flow rate can be associated with speed at which CNTs reach the filter paper 210 and can improve distribution of the CNTs. Pressure can be associated with aerosol dynamics and packing density of the CNTs on the filter paper 210. Temperature can be selected to evaporate solvent in the case of liquid aerosols or to prevent condensation.

During the deposition process, as the CNT aerosol approaches the filter paper 210, the CNTs collide with and stick to the fibers of the filter paper 210. Larger or agglomerated CNTs may be forced onto the paper by inertia thereof. Smaller CNTs or individual nanotubes may be captured through Brownian motion. Pore size and structure of the filter paper 210 are selected to increase efficiency of capture of the CNTs by the filter paper 210. Following the deposition process, the CNTs are present on the filter paper 210 as the first nanotube layer 220.

In embodiments in which a solvent is used, the solvent may be evaporated either through natural drying or by applying heat or a vacuum. In some embodiments, the deposition process can include a step where the CNTs are fixed onto the filter paper 210 through additional treatments, such as thermal annealing or chemical bonding to ensure the CNTs remain in place.

In FIG. 2C, following formation of the first nanotube layer 220, a first capping or “binding” layer 230 is formed on the first nanotube layer 220. In some embodiments, the first capping layer 230 is or includes Ru, Nb, Al, Mo, Si, SiO₂, BN, BC, B, C, N, P, O, molecules thereof, alloys thereof, or the like. In some embodiments, the first capping layer 230 is or includes a metal oxide, a metal oxynitride, or the like, such as an oxide or oxynitride of Ru, Nb, Al, Mo, or the like. The first capping layer 230 is operable to constrict movement of the nanotubes of the first nanotube layer 220. Namely, the first nanotube layer 220 prior to deposition of the first capping layer 230 may be a loose, sparse layer of individual nanotubes that are not substantially bound to each other. Following formation of the first capping layer 230, some or all of the nanotubes may be coated by or embedded in the first capping layer 230, which improves stability of the first nanotube layer 220.

In some embodiments, the combination of the first nanotube layer 220 and the first capping layer 230 has thickness that does not exceed about 5 nm, which is beneficial to achieve improved EUV transmission (e.g., about 90% to about 98%) and improved exposure durability. Adhesion between the first nanotube layer 220 and the first capping layer 230 can be by Van der Waals force, which can include surface intermixing between the nanotubes and material of the first capping layer 230. The nanotube structure of a combined layer 260 including the first nanotube layer 220 and the first capping layer 230 having inter-entanglement between the nanotubes and the material of the first capping layer 230 as an intermixed layer is beneficial to increase membrane strength thereof.

In some embodiments, the first capping layer 230 is formed by a suitable deposition process, which can include physical vapor deposition (PVD), chemical vapor deposition (CVD), plasma-enhanced CVD (PECVD), atomic layer deposition (ALD), or the like. Selecting surface coating grain size of material of the first capping layer 230 to be within a range of about 1 nm to about 10 nm can be beneficial to improve uniformity and binding quality to the first nanotube layer 220. In some embodiments, a dopant is included in the deposition process. In some embodiments, the dopant is or include V, Ti, or another suitable dopant. The dopant can form incomplete interface bonds between grains and reduce surface tension of the deposited material of the first capping layer 230, which is beneficial to improve EUV tolerance of the material. Selection and concentration of the dopant material(s) may be a multifactor or multidimensional consideration based on type of nanotubes of the first nanotube layer 220, material of the first capping layer 230, reaction conditions (e.g., temperature, pressure, precursor gas flow rates, pellicle application) for forming the material of the first capping layer 230, and the like. In some embodiments, concentration of the dopant is in a range of about 7 at % to about 10 at %. Other suitable concentrations that are outside the stated range are also considered as embodiments herein. In some embodiments, the dopant(s) form oxides or oxynitrides that are deposited with a base material (e.g., Ru, Mo, Al, Nb, oxides thereof, oxynitrides thereof, etc.) of the first capping layer 230. For example, the dopant(s) may form TiOₓN_{y}, VOₓN_{y}, or the like during the deposition process. The choice and concentration of the dopant can result in an intermixing interface between the nanotubes and the first capping layer 230, affecting thickness in a range of about 0 nm to about 3 nm. In some embodiments, the dopant penetrates to a depth and has a concentration that follows a gradient profile. For example, concentration of the dopant may decrease from a surface of the first nanotube layer 220 to an interior of the first nanotube layer 220.

In FIG. 2D, following formation of the combined layer 260 including the first nanotube layer 220 and the first capping layer 230, a frame 240 is mounted to the combined layer 260. In some embodiments, the frame 240 has shape or profile in a plane including the first direction D1 and a third direction D3 that is square, rectangular, circular, elliptical, or another suitable shape. The frame 240 may have ring shape that exposes portions of the combined layer 260 that are not in contact with the frame 240. In some embodiments, the frame 240 has shape that is substantially similar to a border of the combined layer 260, a border of the substrate 210, or both. For example, the frame 240 may have a first dimension (e.g., length) that extends along the first direction D1 that is substantially the same as that of the substrate 210, and may have a second dimension (e.g., width) that extends along the third direction D3 that is substantially the same as that of the substrate 210. In some embodiments, the frame 240 is or includes a polymer, such as polymethyl methacrylate (PMMA), polycarbonate (PC), polystyrene (PS), polyester (PET, PETG), polyvinyl chloride (PVC), or the like.

In FIG. 2E, following mounting of the frame 240 to the combined layer 260, the combined layer 260 is removed from the substrate 210. In some embodiments, the combined layer 260 and the frame 240 thereon are lifted off of the substrate 210. In some embodiments, the substrate 210 is peeled off of the combined layer 260.

Then, following removing the combined layer 260 from the substrate 210, the combined layer 260 is flipped and the frame 240 is mounted to a second substrate 250, which may be similar in most respects to the substrate 210, such as filter paper or the like.

Following mounting the frame 240 to the second substrate 250, a second nanotube layer 222 is deposited on the combined layer 260. The second nanotube layer 222 may be similar in most respects to the first nanotube layer 220 and may be formed by a process similar in most respects to that which forms the first nanotube layer 220. In some embodiments, the nanotubes of the second nanotube layer 222 can be or include carbon nanotubes (CNT), boron-doped carbon nanotubes (BCNT), boron nitride nanotubes (BNNT), and the like. Including at least two layers of nanotubes is beneficial to improve strength of the pellicle assembly 200, which can include tensile and/or compressive strengths. Including only a single layer of nanotubes, such as the first nanotube layer 220 without the second nanotube layer 222 can result in an increase in deformation when air pressure is applied.

In FIG. 2F, following formation of the second nanotube layer 222, a second combined layer 262 is formed by forming a second capping layer 232 on the second nanotube layer 222. The second capping layer 232 is similar in most respects to the first capping layer 230 and may be formed by a process similar in most respects to that which forms the first capping layer 230. In some embodiments, the second capping layer 232 is or includes Ru, Nb, Al, Mo, Si, SiO₂, BN, BC, B, C, N, P, O, molecules thereof, alloys thereof, or the like. In some embodiments, the second capping layer 232 is or includes a metal oxide, a metal oxynitride, or the like, such as an oxide or oxynitride of Ru, Nb, Al, Mo, or the like. In some embodiments, the second capping layer 232 includes one or more of the dopants described with reference to FIG. 2C. Generally, it is beneficial for the second capping layer 232 to be the same material as the first capping layer 230, namely, as close to the same material as possible, which is beneficial to improve mixing or bonding of the first capping layer 230 and the second capping layer 232 with or to each other in a subsequent heating process.

In FIG. 2G, following formation of the second combined layer 262, a composite structure 264 is formed that includes the first and second nanotube layers 220, 222 and a melded layer 234 that is interspersed between and binds nanotubes of the first and second nanotube layers 220, 222. The composite structure 264 is formed by performing a heating process that can benefit melding of the first and second capping layers 230, 232 to each other in various ways. The composite structure 264 is or includes a nanotube-based scaffold structure having nanotubes bound together by a capping layer.

At elevated temperatures, the first and second capping layers 230, 232 may soften or partially melt, allowing for increased intermixing at interfaces where the first and second capping layers 230, 232 meet. When the melting point of the material of the first and second capping layers 230, 232 is approached or reached, the first and second capping layers 230, 232 can fuse together, generating a stronger bond. Heat of the heating process can accelerate atomic diffusion, such that atoms from the second capping layer 232 can diffuse into the adjacent first capping layer 230. Such a mechanism may be more pronounced at higher temperatures, where atomic mobility is increased. In some embodiments, the heating process can trigger or enhance chemical reactions between the materials of the first and second capping layers 230, 232. For example, when MoON reacts with itself or another compound under heat, chemical bonds can form across the interface, effectively melding the first and second capping layers 230, 232. This can include oxidation, reduction, or other chemical interactions depending on the reaction environment (presence of oxygen, nitrogen, etc.). In some embodiments, the heating process may activate surfaces of the first and second capping layers 230, 232, making the surfaces more reactive. This can result in surface oxides or contaminants being removed or broken down, allowing clean, reactive surfaces of the first and second capping layers 230, 232 to come into closer contact or react with each other. In some embodiments, the heating process relieves internal stresses or strains in the materials of the first and second capping layers 230, 232. For example, residual stresses may be present in the first and second capping layers 230, 232 from the deposition or coating process(es), and heating can relax the stresses, allowing the first and second capping layers 230, 232 to conform better to each other. Although typically associated with powders, sintering can occur with thin films under heat, such as the first and second capping layers 230, 232. A particulate nature of the material of the first and second capping layers 230, 232 at the atomic or molecular level can allow for sintering where particles fuse together, increasing bond strength between the first and second capping layers 230, 232. In some embodiments, the first and second capping layers 230, 232 have phase transitions within a temperature range applied during the heating process, which can result in structural realignment or formation of a phase that is more conducive to bonding with the adjacent layer.

In the heating process, selection of temperature, time, presence or absence of gases, pressure and the like may be beneficial to improve intermixing or melding between the first and second capping layers 230, 232. In some embodiments, the temperature is in a range that is high enough to promote sintering, diffusion or melting (e.g., exceeding about 300° C.) but below degradation temperatures of the nanotubes and the material of the first and second capping layers 230, 232 (e.g., not exceeding about 600° C., 1000° C. or another suitable value). Longer exposure times at selected temperatures can enhance melding through diffusion or reaction. Presence of selected gases can improve chemical reactions or prevent oxidation where beneficial. In some embodiments, pressure is applied during heating, which can enhance bonding by pressing the first and second capping layers 230, 232 closer together.

Melding between the first and second capping layers 230, 232 can result in improved mechanical integrity, thermal stability or both of the composite structure 264 without degrading the nanotubes themselves during the heating process, for example, by exposure to high temperatures in the presence of oxygen or other reactive gases. Namely, the nanotubes can form a scaffold structure in which the nanotubes are bound together by the first and second capping layers 230, 232 that are melded together.

FIG. 2H illustrates a schematic view of the composite structure 264 of the pellicle assembly 200 along cross-sectional line H-H of FIG. 2G, in accordance with some embodiments.

In FIG. 2H, the melded layer 234 covers the nanotubes of the first and second nanotube layers 220, 222. In some embodiments, as depicted, the melded layer 234 is a continuous layer along the second direction D2 that has substantially no voids or openings therein that are not filled by a nanotube. For example, the melded layer 234 may have thickness H1 in the second direction D2 that is substantially uniform over area of the melded layer 234 in the first and third directions D1, D3. In some embodiments, the thickness H1 is not uniform along the first and/or third directions D1, D3. For example, material of the melded layer 234 may be deposited substantially conformally onto the nanotubes of the first and second nanotube layers 220, 222, such that the thickness H1 varies due to gaps between adjacent pairs of individual nanotubes.

FIG. 2H depicts first nanotubes 220a of the first nanotube layer 220 and second nanotubes 222a of the second nanotube layer 222. The first and second nanotubes 220a, 222a are bound together by the melded layer 234.

In some embodiments, the method can further include stacking additional nanotube layers and capping layers similar to the first and second nanotube layers 220, 222 and the first and second capping layers 230, 232 onto the second capping layer 232, which increases thickness H1 of the composite structure 264, which can result in improved structural and thermal stability of the pellicle assembly 200.

The method may include additional operations than those described with reference to FIGS. 2A-2H. For example, following formation of the composite structure 264, the method may include mounting the pellicle assembly 200 to a mask (e.g., the mask 18, 18A) and performing semiconductor processing of a wafer (e.g., the wafer 22, 22A) by the mask having the pellicle assembly 200 mounted thereon.

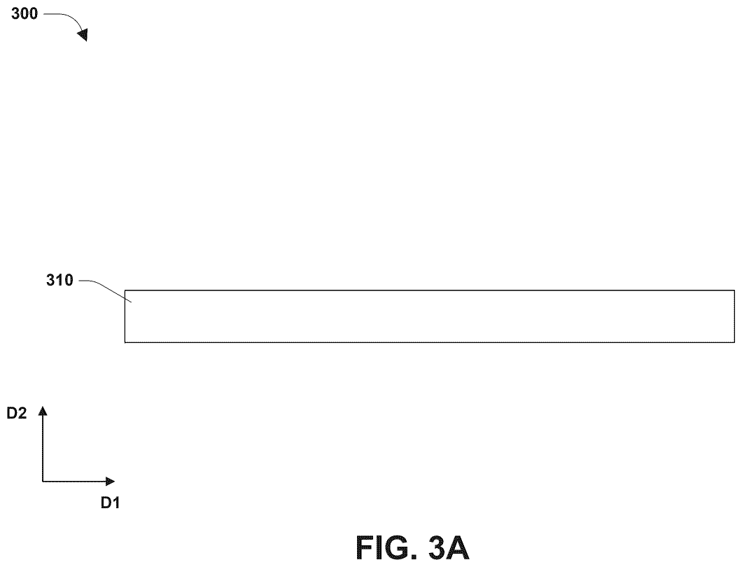

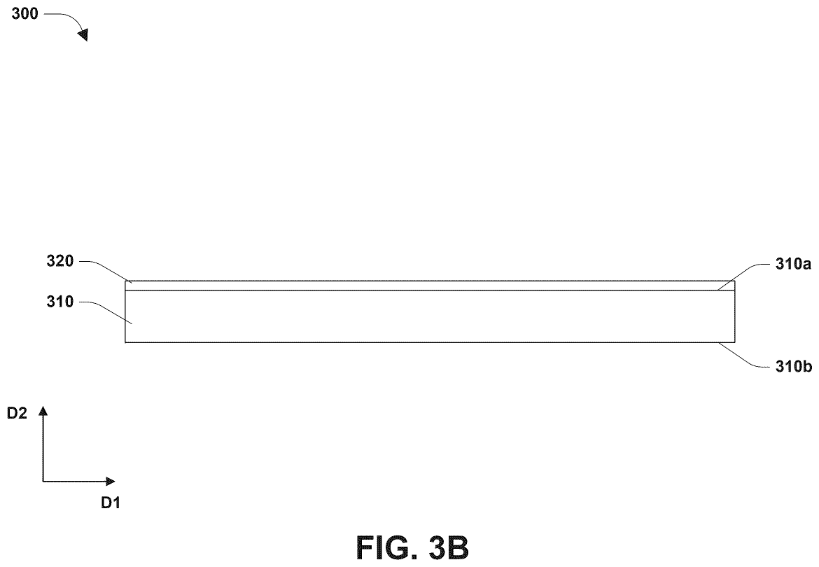

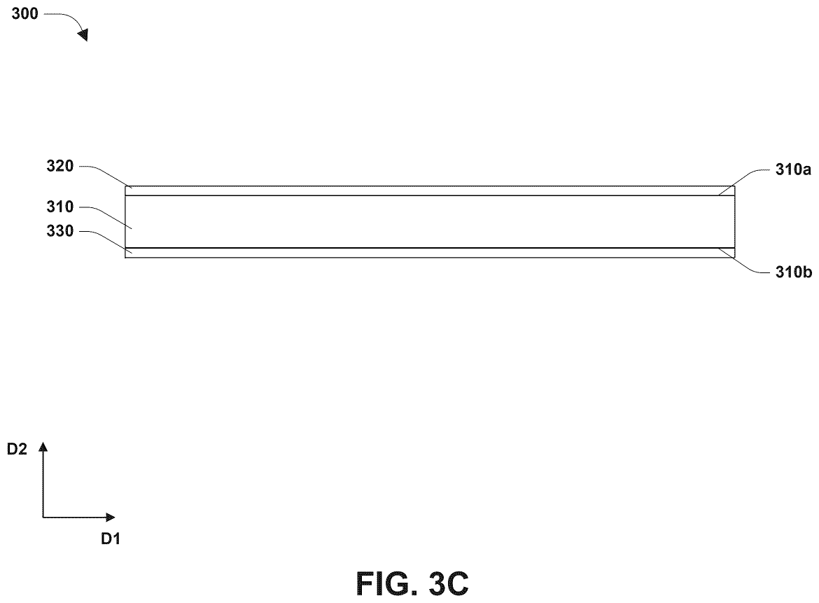

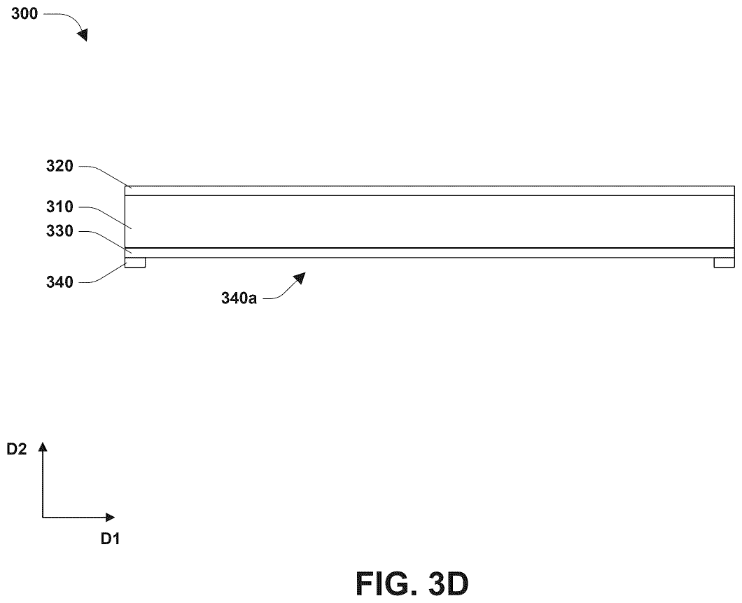

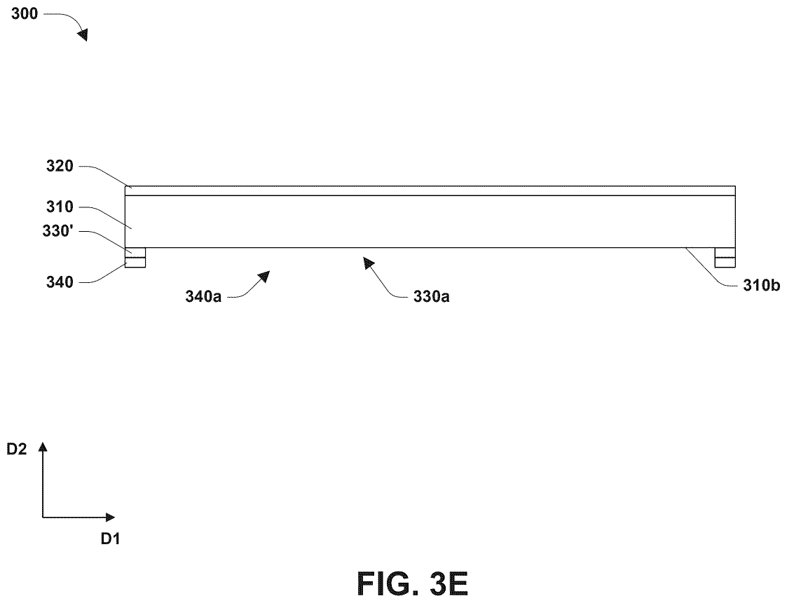

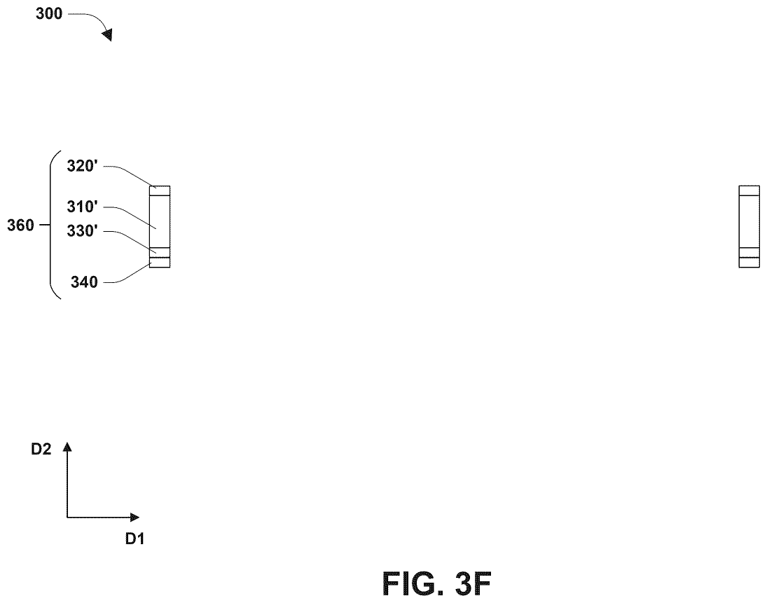

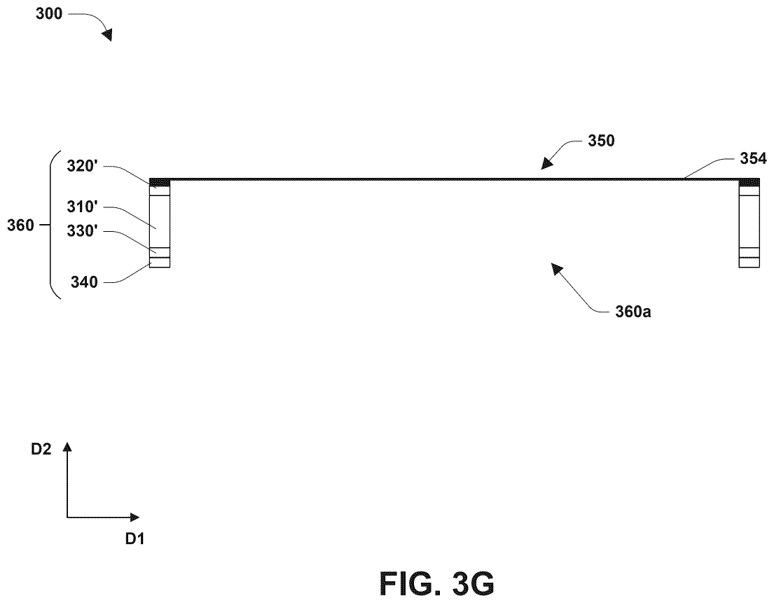

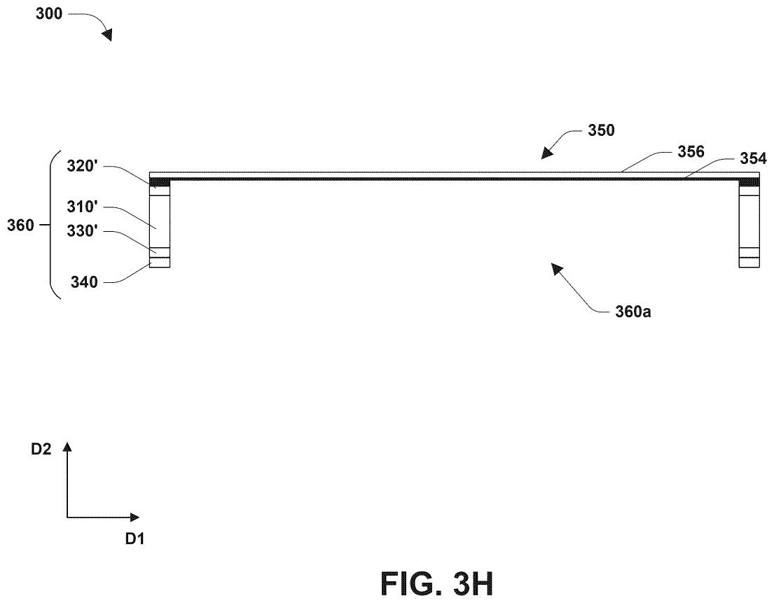

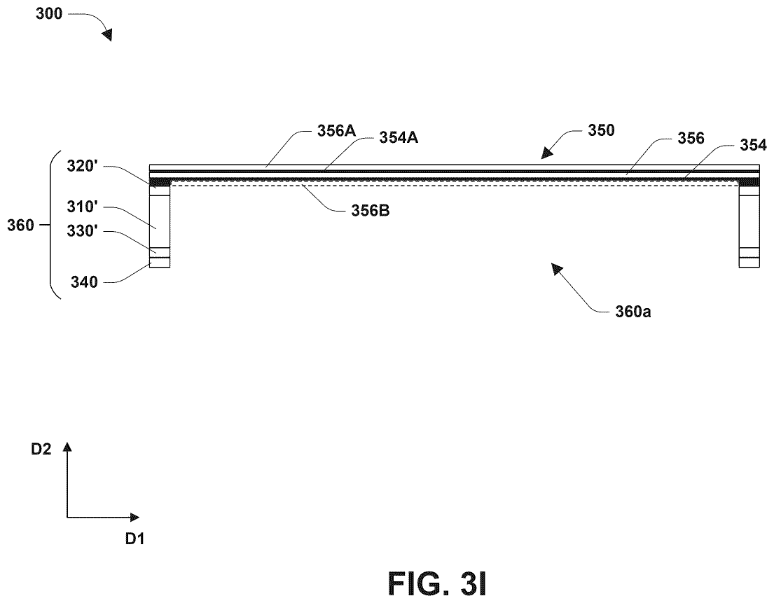

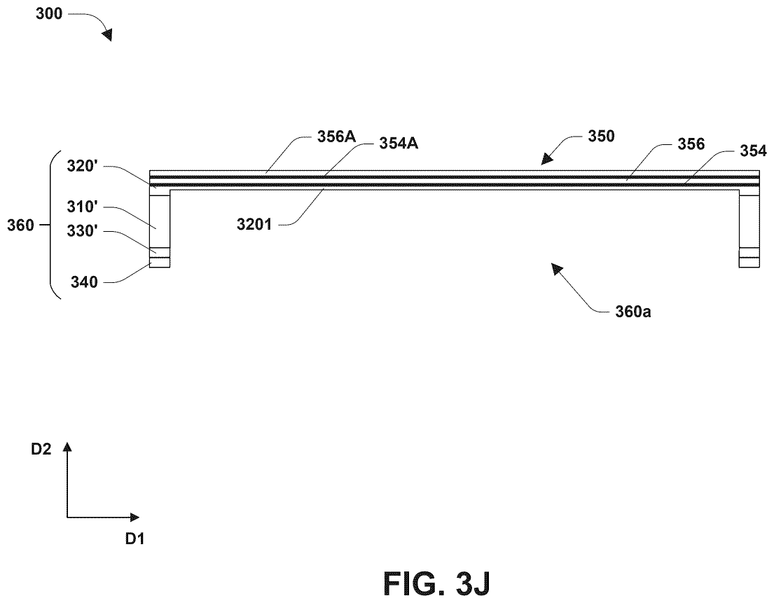

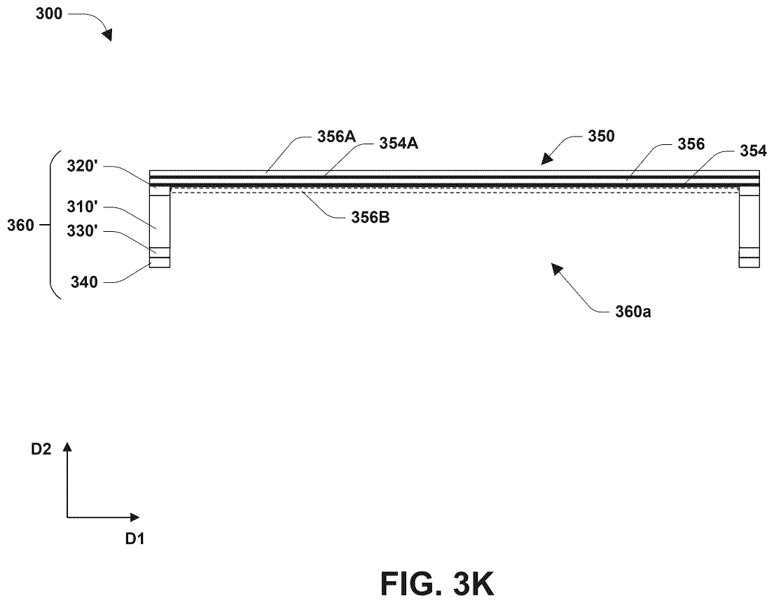

FIGS. 3A, 3B, 3C, 3D, 3E, 3F, 3G, 3H, 3I, 3J and 3K illustrate schematic views of methods of forming a pellicle assembly 300, in accordance with some embodiments.

In FIG. 3A, a substrate 310 is provided. In some embodiments, the substrate 310 is or includes a semiconductor wafer, which may be similar in most respects to the semiconductor wafers 22, 22A described with reference to FIGS. 1A-1C.

In FIG. 3B, following providing the substrate 310, a capping or “sacrificial” layer 320 is formed on the substrate 310. The capping layer 320 may be or include a layer of dielectric material, such as SiO₂, SiN, SiCN, SiON, SiOCN, Al₂O₃, HfO₂, spin-on glass, organic polymer, TiN, combinations thereof, and the like. The capping layer 320 may be formed by a suitable process, which may include PVD, CVD, ALD, or the like. The capping layer 320 is formed on a first side 310a of the substrate 310. The first side 310a may be a major surface of the substrate 310.

In FIG. 3C, following formation of the capping layer 320, a hard mask layer 330 is formed on the substrate 310. In some embodiments, the hard mask layer 330 is or includes amorphous carbon (a-C), silicon nitride, silicon dioxide, a metal oxide (e.g., aluminum oxide, hafnium oxide, or the like), a metal nitride (e.g., titanium nitride), tungsten, a spin-on hard mask (e.g., spin-on-carbon), combinations or multilayers thereof, or the like. The hard mask layer 330 may be formed by a suitable process, which can include, PVD, CVD, ALD, or the like. The hard mask layer 330 is formed on a second side 310b of the substrate 310. The second side 310b may be a major surface of the substrate 310 that is opposite to and faces away from the first side 310a.

In FIG. 3D, following formation of the hard mask layer 330, a patterned photosensitive layer 340 is formed on the hard mask layer 330. In some embodiments, the photosensitive layer 340 is a photosensitive resist layer, which can include a positive tone or negative tone resist. A process of forming and patterning the photosensitive layer 340 on the hard mask layer 330 follows. Initially, the hard mask layer 330 may be cleaned and optionally primed with an adhesion promoter. Photoresist is then applied by spin coating, where the photoresist is dispensed onto the hard mask layer 330 and spun to achieve a uniform thin film, followed by a soft bake to remove solvents and improve adhesion. Patterning can include aligning the substrate 310 under a photomask in a lithography tool for exposure to light, where the photoresist reacts differently depending on whether the photoresist is positive or negative type. Positive resist dissolves where exposed, and negative resist remains. After exposure, a post-exposure bake may be performed to enhance the latent image, then the photoresist is developed to remove either the exposed or unexposed areas, revealing the selected pattern by forming openings 340a, resulting in the patterned photosensitive layer 340. The patterned photosensitive layer 340 then acts as a stencil during subsequent etching of the hard mask layer 330, transferring the pattern into the mask material for further processing, such as etching. Optional hard baking can be performed to solidify the remaining photoresist, enhancing durability thereof for subsequent process steps. In some embodiments, the photosensitive layer 340 defines the opening 340a that is surrounded in the plane formed by the first and third directions D1, D3 by a border.

In FIG. 3E, following formation of the patterned photosensitive layer 340, the hard mask layer 330 is patterned through the opening 340a of the photosensitive layer 340, resulting in a patterned hard mask layer 330′. The patterning may be by a suitable etching operation that attacks material of the hard mask layer 330 without substantially attacking materials of the photosensitive layer 340 and the underlying substrate 310. In some embodiments, the patterning is directional, and may include an anisotropic etch or “first etch,” such as a plasma etch, which can include reactive ion etching (RIE) or another suitable etching process. Following the first etch, the second side 310b of the substrate 310 may be exposed through openings 340a, 330a in the photosensitive layer 340 and the patterned hard mask layer 330′, respectively.

In FIG. 3F, following formation of the opening 330a defined by the patterned hard mask layer 330′, the substrate 310 and the sacrificial layer 320 may be patterned through the patterned hard mask layer 330′, resulting in a patterned substrate 310′ and a patterned sacrificial layer 320′. The patterning may include an anisotropic etch or “second etch,” which may be similar in many respects to the first etch (e.g., may be an RIE) and may use etchant(s) that instead attack one of the substrate 310 or the sacrificial layer 320 without substantially attacking others of the photosensitive layer 340, the patterned hard mask layer 330′, the substrate 310 and the sacrificial layer 320. The second etch generally etches entirely through the substrate 310. In some embodiments, the second etch etches partially or fully through the sacrificial layer 320. An embodiment in which the second etch etches partially through the sacrificial layer 320 is described with reference to FIGS. 3J and 3K. Following the second etch, a resulting structure or frame 360 includes the photosensitive layer 340, the patterned hard mask layer 330′, the patterned substrate 310′ and the patterned sacrificial layer 320′. The frame 360 is operable to support a pellicle membrane 350 that may be similar in many respects to the composite structure 264 described with reference to FIGS. 2A-2H. Formation of the pellicle membrane 350 is described in accordance with some embodiments with reference to FIGS. 3G-3I and in accordance with some other embodiments with reference to FIGS. 3J and 3K.

In FIG. 3G, following formation of the frame 360, a first nanotube layer 354 is formed on the frame 360. The first nanotube layer 354 is formed on the patterned sacrificial layer 320′ and extends across an opening 360a defined in the frame 360. The first nanotube layer 354 may be similar in most respects to the first nanotube layer 220 described with reference to FIGS. 2A-2H. In some embodiments, the first nanotube layer 354 is or includes CNTs, BCNs, or the like, and may be formed by a deposition process similar to that described with reference to FIGS. 2A-2H.

In the deposition process, the first nanotube layer 354 may be formed by depositing CNTs on the frame 360. The deposition process is described with reference to CNTs, but may be performed similarly to deposit BCNs or other suitable nanostructures. In some embodiments, the deposition process includes depositing carbon nanotubes (CNTs) on the frame 360 via a carrier gas. In some embodiments, the CNTs are initially dispersed in a liquid medium (e.g., ethanol or water) with the aid of surfactants or sonication to prevent aggregation, which is beneficial for the CNTs to be well-dispersed prior to aerosolization. Then, the CNT suspension can be aerosolized using one or more operations, which can include atomization, electrospray, or the like. Atomization can include spraying the suspension into a carrier gas to create an aerosol. Electrospray can include using an electric field to disperse the CNTs into fine droplets. In some embodiments, a carrier gas is introduced. In some embodiments, the carrier gas is or includes an inert gas, such as argon, nitrogen or the like. The carrier gas can carry the CNTs towards the frame 360. Selection of the carrier gas can improve deposition efficiency and behavior of CNTs due to differences in gas properties, such as density or viscosity. The CNT-laden gas stream is directed towards the frame 360. Flow rate, pressure, and temperature of the carrier gas can be selected to improve yield of the deposition process. The flow rate can be associated with speed at which CNTs reach the frame 360 and can improve distribution of the CNTs. Pressure can be associated with aerosol dynamics and packing density of the CNTs on the frame 360. Temperature can be selected to evaporate solvent in the case of liquid aerosols or to prevent condensation.

Initially, the CNTs may settle mostly on the frame 360 itself, such as on the patterned sacrificial layer 320′. Then, the first nanotube layer 354 may merge over time to form a continuous layer over the opening 360a. The first nanotube layer 354 may be continuous and porous due to the arrangement of the individual nanotubes as a sparse network.

In FIG. 3H, following formation of the first nanotube layer 354, a first capping layer 356 is formed on the first nanotube layer 354. The first capping layer 356 is similar in most respects to the first capping layer 230 described with reference to FIGS. 2A-2H. The first capping layer 356 can be formed by a process similar to that described with reference to the first capping layer 230.

In FIG. 3I, following formation of the first capping layer 356, a second nanotube layer 354A is formed on the first capping layer 356. Then, a second capping layer 356A is formed on the second nanotube layer 354A. Following formation of the second nanotube layer 354A and the second capping layer 356A, a thermal process (e.g., an anneal) is performed that forms the pellicle membrane 350 having the first and second capping layers 356, 356A that are melded with each other, as described with reference to FIGS. 2A-2H.

A method of forming a pellicle membrane 350 on a frame 360 is described with reference to FIGS. 3A-3I, in accordance with some embodiments. In some embodiments, an additional capping layer deposition process may be performed that deposits a third capping layer 356B similar to the first and second capping layers 356, 356A onto a backside of the first nanotube layer 354 opposite a frontside thereof on which the first capping layer 356 is positioned. The third capping layer 356B can be similar in most respects to the first and second capping layers 356, 356A. Deposition of the third capping layer 356B can be during deposition of the first capping layer 356, the second capping layer 356A, or both. In some embodiments, the third capping layer 356B is deposited (i) following the first capping layer 356 and prior to the second nanotube layer 354A, (ii) following the second nanotube layer 354A and prior to the second capping layer 356A, or (iii) following the second capping layer 356A.

In some embodiments, instead of depositing the individual layers, such as the first and second nanotube layers 354, 354A and the first, second and optional third capping layers 356, 356A, 356B, onto the frame 360 via one or more deposition processes, the pellicle membrane 350 is formed via a process similar in most respects to that described with FIGS. 2A-2H separate from the frame 360. Then, the pellicle membrane 350 similar to the composite structure 264 is mounted to the frame 360, which can include mounting via an adhesive, mounting screws, or another suitable mechanism.

FIGS. 3J and 3K depict an embodiment of the method described with reference to FIGS. 3A-3I in which the sacrificial layer 320 is partially removed, leaving a thin layer 3201 of the patterned sacrificial layer 320′ that extends across the opening 360a.

In FIG. 3J, following patterning of the sacrificial layer 320′, the first nanotube layer 354 is formed on the thin layer 3201, as described with reference to FIG. 3H. The first nanotube layer 354 formed on the thin layer 3201 may have substantially uniform thickness in the plane formed by the first and third directions D1, D3. Namely, instead of initially building up on edges of the patterned sacrificial layer 320′ then merging over the opening 360a as described with reference to FIG. 3H, the first nanotube layer 354 formed on the thin layer 3201 may build up evenly across the edges and over the opening 360a, resulting in substantially uniform thickness of the first nanotube layer 354. Then, similar to described with reference to FIGS. 3H and 3I, the first capping layer 356, the second nanotube layer 354A and the second capping layer 356A are formed sequentially on the first nanotube layer 354.

In FIG. 3K, following formation of the first nanotube layer 354, the first capping layer 356, the second nanotube layer 354A and the second capping layer 356A, the thin layer 3201 is removed by a suitable etching process, which may be an anisotropic etching process, such as a plasma etch. Following removal of the thin layer 3201, the optional third capping layer 356B may be formed as described with reference to FIG. 3I.

In some embodiments, a thermal process (e.g., an annealing process) that melds the first and second capping layers 356, 356A and optionally the third capping layer 356B may be performed (i) prior to removing the thin layer 3201, (ii) following removal of the thin layer 3201 and prior to forming the third capping layer 356B, or (iii) following forming of the third capping layer 356B. The thermal process improves mechanical strength of the pellicle membrane 350 by improving coverage and binding of the nanotubes of the first and second nanotube layers 354, 354A in the material of the first, second and optional third capping layers 356, 356A, 356B.

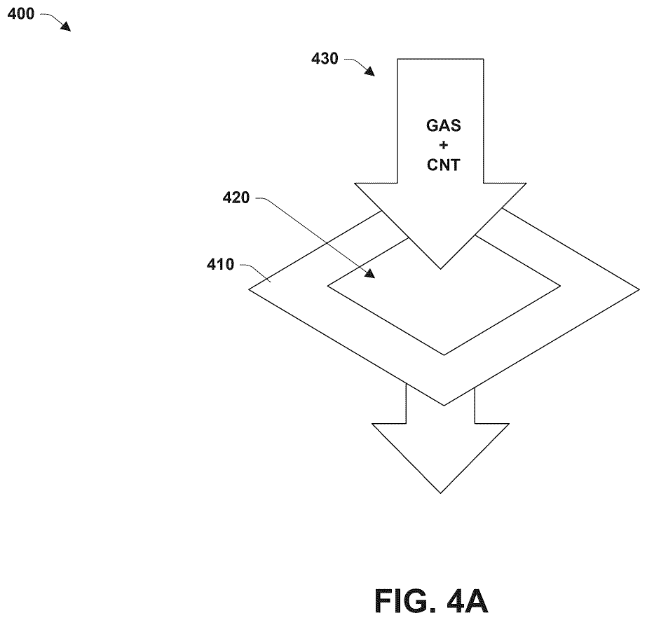

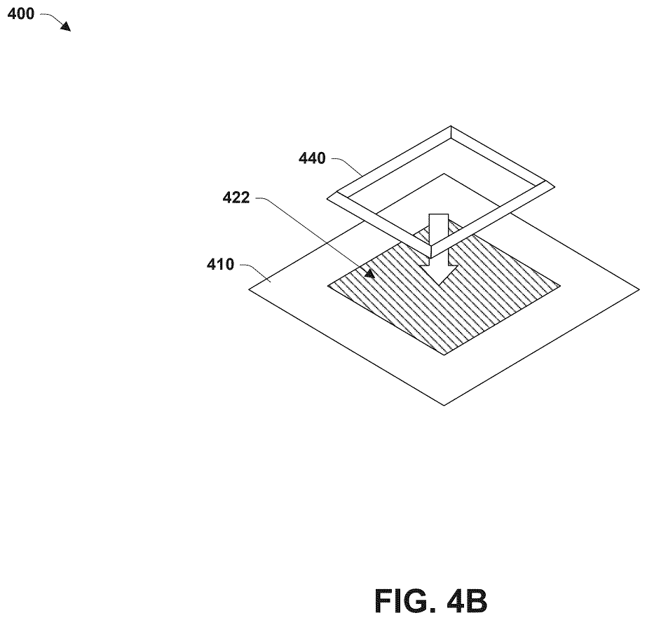

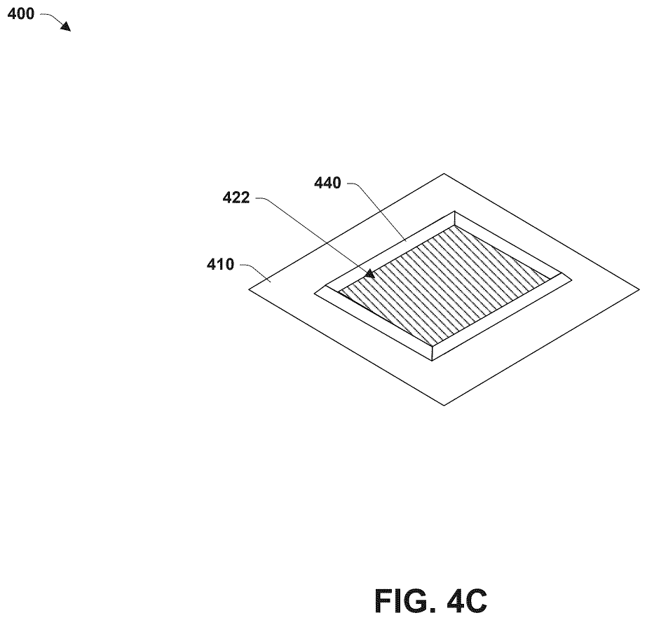

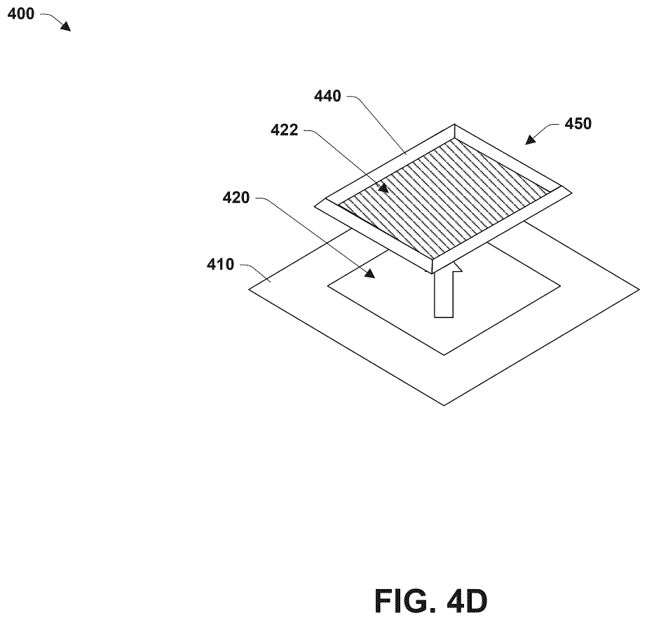

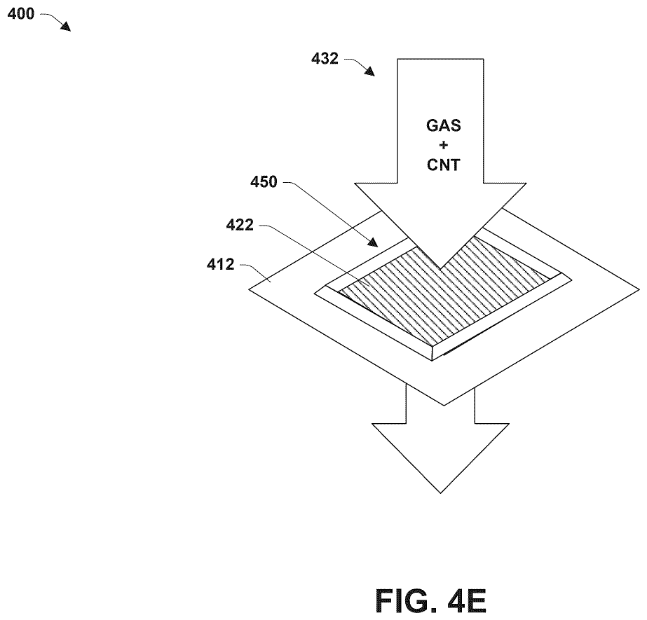

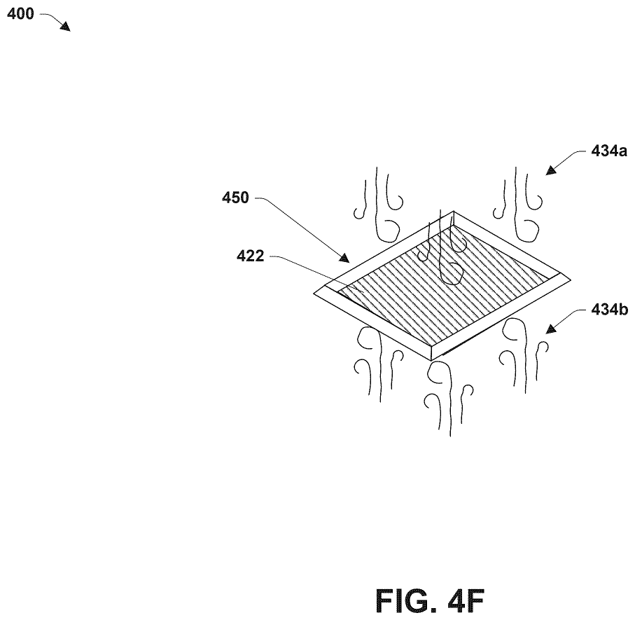

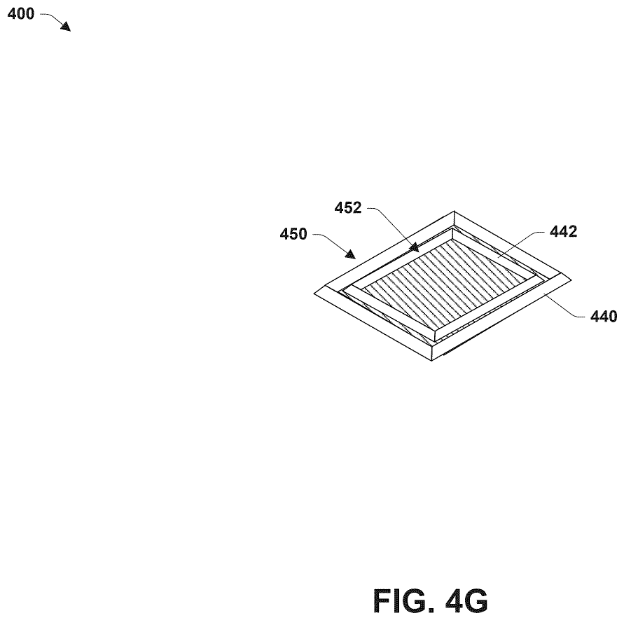

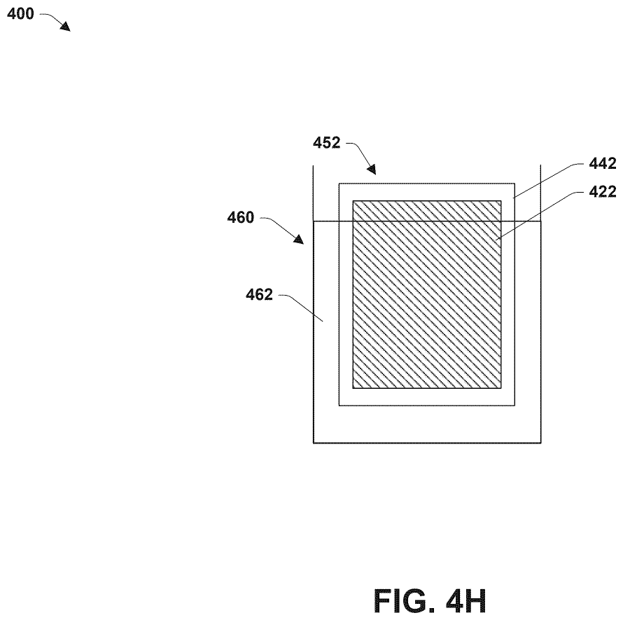

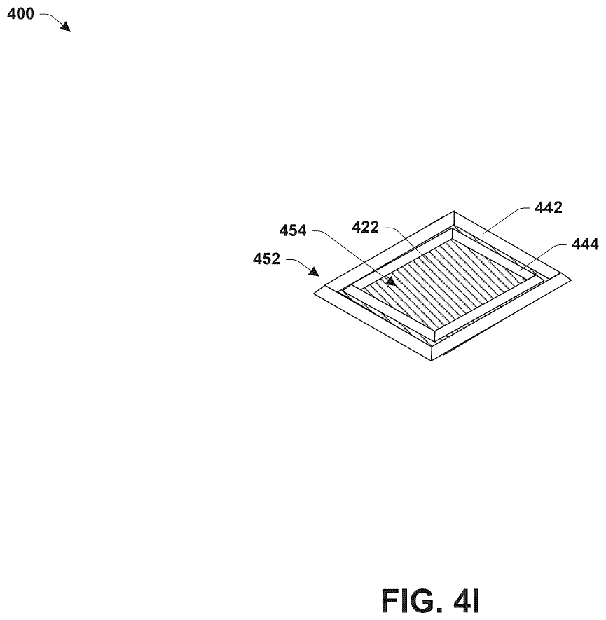

FIGS. 4A, 4B, 4C, 4D, 4E, 4F, 4G, 4H, and 4I illustrate schematic views of a method of forming a pellicle membrane 400, in accordance with some embodiments. Many operations of the method described with reference to FIGS. 4A-4I are similar to those described with reference to FIGS. 2A-2H. The pellicle membrane 400 can be an embodiment of the composite structure 264, the pellicle membrane 350, or both.

In FIG. 4A, the method includes flowing a gas carrying nanotubes (e.g., CNTs) toward a frame 410 having a substrate 420 exposed therethrough. The flowing is indicated by an arrow 430 in FIG. 4A. Flowing the gas carrying nanotubes to form a first nanotube layer 422 (shown in FIG. 2B) on the substrate 420 is similar in most respects to that described with reference to FIGS. 2A and 2B.

In FIG. 4B, following flowing the gas, the first nanotube layer 422 is present on the substrate 420. Then, a membrane or border 440 is lowered onto the first nanotube layer 422. The membrane 440 is similar in most respects to the frame 240 described with reference to FIG. 2D. In some embodiments, the membrane 440 is a PMMA frame that has width in a range of about 50 millimeters (mm) to about 300 mm and has length in a range of about 50 mm to about 300 mm.

In FIG. 4C, the membrane 440 is positioned in contact with the first nanotube layer 422.

In FIG. 4D, the membrane 440 and the first nanotube layer 422 are lifted from the substrate 420. A pellicle membrane structure 450 includes the membrane 440 attached to the first nanotube layer 422, as depicted.

In FIG. 4E, following removing the pellicle membrane structure 450 from the substrate 420, the pellicle membrane structure 450 may be transferred to a second frame 412 that exposes a second substrate (not separately labeled in FIG. 4E for simplicity). The second substrate can be similar in most respects to the substrate 420. Then, the method includes flowing a second gas carrying second nanotubes (e.g., CNTs) toward the frame 412 having the second substrate exposed therethrough. The flowing is indicated by an arrow 432 in FIG. 4E. Flowing the gas carrying second nanotubes can increase density of nanotubes in the pellicle membrane structure 450, and can be similar in most respects to the process described with reference to FIGS. 2A and 2B.

In FIG. 4F, following densifying the first nanotube layer 422 in FIG. 4E, the nanotubes of the first nanotube layer 422 may be further densified by flowing an upper gas 434a and a lower gas 434b toward the first nanotube layer 422. The upper gas 434a may flow downward toward a first side (or “upper side”) of the first nanotube layer 422. The lower gas 434b may flow upward toward a second side (or “lower side”) of the first nanotube layer 422. The upper and lower gases 434a, 434b can apply pressure to the first nanotube layer 422, which improves density of arrangement of the nanotubes thereof.

In some embodiments, the operations described with reference to FIGS. 4D-4F may be repeated at least two times, which can result in increased densification of the first nanotube layer 422.

In FIG. 4G, following densification of the first nanotube layer 422, a frame or “border” 442 may be attached to the first nanotube layer 422. The frame 442 may have width and length that are smaller than those of the membrane 440. In some embodiments, the frame 442 is or includes quartz. Following attaching the frame 442, a second pellicle membrane structure 452 includes the frame 442 and the first nanotube layer 422. The second pellicle membrane structure 452 may be lifted and removed from the membrane 440.

In FIG. 4H, following formation of the second pellicle membrane structure 452 in FIG. 4G, the second pellicle membrane structure 452 may be washed. The washing can include submerging the second pellicle membrane structure 452 in a tank 460 containing a solvent 462. In some embodiments, the solvent 462 is or includes an organic solvent, an aqueous solution, a surfactant solution, or the like. The second pellicle membrane structure 452 may be submerged in the solvent 462 at least one time. In some embodiments, the solvent 462 is agitated to increase motion of the solvent 462 relative to the second pellicle membrane structure 452 submerged therein.

In FIG. 4I, following washing of the second pellicle membrane structure 452, a pellicle membrane 454 is formed by transferring the first nanotube layer 422 from the frame 442 to a second frame 444. In some embodiments, the second frame 444 is or includes a silicon border that is attached to the first nanotube layer 422. Then, the second frame 444 and the first nanotube layer 422 attached thereto may be lifted and removed from the frame 442. The pellicle membrane 454 can be attached to a frame (e.g., the frame 360) to form a pellicle assembly (e.g., the pellicle assembly 300) that can be attached to a mask (e.g., the mask 18 or the mask 18A).

In the method described with reference to FIGS. 4A-4I, capping layers similar in most respects to the first, second and optional third capping layers 356, 356A, 356B may be deposited on the first nanotube layer 422. Two or more capping layers may be deposited on the first nanotube layer 422 at various points during the method, including one or more of (i) following removing the first nanotube layer 422 in FIG. 4D and prior to depositing the second nanotubes in FIG. 4E, (ii) following depositing the second nanotubes in FIG. 4E and prior to flowing the upper and lower gases 434a, 434b in FIG. 4F, (iii) following flowing the upper and lower gases 434a, 434b in FIG. 4F and prior to depositing the second nanotubes in FIG. 4E or attaching the frame 442 in FIG. 4G, (iv) following attaching the frame 442 in FIG. 4G and prior to washing the second pellicle membrane structure 452 in FIG. 4H, (v) following washing the second pellicle membrane structure 452 in FIG. 4H and prior to attaching the second frame 444, and/or (vi) following attaching the second frame 444.

Following deposition of at least two of the two or more capping layers, an annealing operation may be performed to meld the at least two capping layers, as described with reference to FIGS. 2A-3K.

Including the capping layers and nanotube material, such as CNT, is beneficial for the pellicle membrane 454 to have improved strength, improved durability in an EUV exposure environment, and improved transmission in the DUV and EUV spectrums.

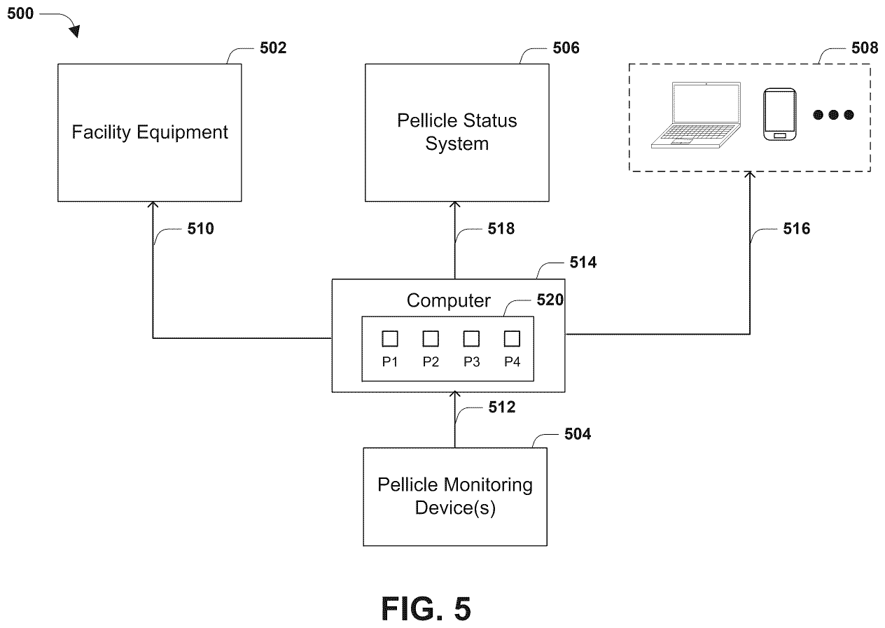

FIG. 5 illustrates a schematic view of a pellicle assembly monitoring system or “system” 500, in accordance with some embodiments. The system 500 comprises at least one of a set of pellicle assembly monitoring devices 504, facility equipment 502 of a facility, a computer 514, a pellicle assembly status system 506, or one or more client devices 508. The set of pellicle assembly monitoring devices 504 comprises pellicle assembly monitoring devices distributed at various locations of the facility. The pellicle assembly monitoring devices are used to determine measurements associated with devices and/or other equipment in the facility, such as the systems 10, 10A described with reference to FIGS. 1A-1C. In some embodiments, the pellicle assembly monitoring devices are used to determine measurements associated with the pellicle assemblies 19, 19A, 200, 300 described with reference to FIGS. 1A-4I.

In some embodiments, the set of pellicle assembly monitoring devices 504 transmit a set of monitoring signals 512 to the computer 514. In some embodiments, each signal of the set of monitoring signals 512 is transmitted by a monitoring device of the set of pellicle assembly monitoring devices 504, in a system of the facility.

In some embodiments, the set of monitoring signals 512 comprises a first monitoring signal from a first pellicle assembly monitoring device. For example, the first pellicle assembly monitoring device may determine whether a pellicle assembly is damaged based on defects (e.g., bridging defects) detected on a wafer patterned using a mask assembly protected by the pellicle assembly. In some embodiments, the first pellicle assembly monitoring device comprises a wireless communication module that transmits the first monitoring signal to the computer 514 wirelessly. In some embodiments, the first pellicle assembly monitoring device transmits the first monitoring signal to the computer 514 over a wired connection between the first pellicle assembly monitoring device and the computer 514. In some embodiments, the first monitoring signal is indicative of defects associated with the pellicle membrane of the pellicle assembly.

In some embodiments, the set of monitoring signals 512 comprises a second monitoring signal from a second pellicle assembly monitoring device. In some embodiments, the second monitoring signal is indicative of brightness associated with light exiting the mask assembly having the pellicle assembly mounted thereon.

In some embodiments, the computer 514 controls a display panel 520 comprising a set of status indicators associated with apparatuses (e.g., first, second, third and fourth pellicle assemblies indicated by “P1,” “P2,” “P3,” and “P4,” respectively) of the system in the facility. In some embodiments, an indicator of the set of status indicators comprises a light, such as an indicator light, that indicates whether a corresponding apparatus is associated with a degraded pellicle assembly, wherein the light being in a first state indicates that the corresponding apparatus is associated with the degraded pellicle assembly and/or the light being in a second state indicates that the corresponding apparatus is not associated with the degraded pellicle assembly. In some embodiments, the display panel 520 comprises a display configured to display an alert indicative of one or more detected pellicle assembly monitoring statuses of one or more apparatuses. In some embodiments, the first state corresponds to a first color emitted by the light, such as red or other color, and the second state corresponds to a second color emitted by the light, such as green or other color. The set of status indicators comprises at least one of a first indicator “P1” associated with a first apparatus, a second indicator “P2” associated with a second apparatus, a third indicator “P3” associated with a third apparatus, a fourth indicator “P4” associated with a fourth apparatus, or other indicator.

In some embodiments, the computer 514 provides one or more first signals 510 to the facility equipment 502. In some embodiments, the one or more first signals 510 are used to control at least some of the facility equipment 502, such as a lithography system of the facility and/or other equipment of the facility. In some embodiments, the one or more first signals 510 are generated using a signal generator of the computer 514. The one or more first signals 510 can be indicative of a degraded pellicle assembly of the lithography system. In some embodiments, the computer 514 transmits the one or more first signals 510 to the facility equipment 502 wirelessly, such as using a wireless communication device of the computer 514. In some embodiments, the computer 514 transmits the one or more first signals 510 to the facility equipment 502 over a physical connection between the computer 514 and the facility equipment 502. In some embodiments, the computer 514 transmits the one or more first signals 510 to a controller that controls one or more operations of the lithography system. In some embodiments, the controller controls removal of the pellicle assembly, the mask assembly having the pellicle assembly thereon, or both, for example, by a robot arm.

In some embodiments, the computer 514 transmits a second signal 518 to the pellicle assembly status system 506. The second signal 518 is generated using the signal generator of the computer 514. In some embodiments, the second signal 518 is indicative of at least one of (i) the set of pellicle assembly monitoring statuses, (ii) the list of apparatuses that are determined to have the degraded pellicle assembly, or (iii) other information. In some embodiments, the computer 514 transmits the second signal 518 to the status system 506 wirelessly, such as using the wireless communication device of the computer 514. In some embodiments, the computer 514 transmits the second signal 518 to the status system 506 over a physical connection between the computer 514 and the status system 506. In some embodiments, the status system 506 triggers an alarm function based upon the second signal 518. In some embodiments, the status system 506 triggers the alarm function based upon the second signal 518 indicating that the pellicle assembly is degraded. In some embodiments, in response to triggering the alarm function, an alarm message is displayed via a display of the status system 506. The alarm message comprises at least one of an indication that the pellicle assembly is degraded, an indication of lead time to perform preventative maintenance, an indication comprising an instruction for the associated lithography system to cease operating (until the pellicle assembly is replaced, for example), or other indication. In some embodiments, an alarm sound is output via a speaker connected to the pellicle assembly status system 506 in response to triggering the alarm function.

In some embodiments, the computer 514 transmits a third signal 516 to one or more client devices 508. The one or more client devices 508 comprise at least one of a phone, a smartphone, a mobile phone, a landline, a laptop, a desktop computer, hardware, or other type of client device. The third signal 516 is generated using the signal generator of the computer 514. In some embodiments, the third signal 516 is indicative of at least one of (i) the set of pellicle assembly monitoring statuses, (ii) the list of apparatuses that are determined to be associated with the pellicle assembly that is degraded, or (iii) other information. In some embodiments, the computer 514 transmits the third signal 516 to a client device of the one or more client devices 508 wirelessly, such as using the wireless communication device of the computer 514. In some embodiments, the computer 514 transmits the third signal 516 to a client device of the one or more client devices 508 over a physical connection between the computer 514 and the client device. In some embodiments, the third signal 516 comprises a message, such as at least one of an email, a text message, etc., transmitted in response to detecting the pellicle assembly that is degraded. In some embodiments, in response to detecting a pellicle assembly is degraded, a telephonic call is made to a client device, such as a landline or a mobile phone, of the one or more client devices 508, such as using a dialer of the computer 514.

In some embodiments, the set of monitoring signals 512 are used as feedback based upon which operation of the facility equipment 502 is controlled by the computer 514. In some embodiments, the computer 514 controls operation of the facility equipment 502 based upon measurements provided by the set of monitoring signals 512. In some embodiments, operation of the facility equipment 502 is controlled using the one or more first signals 510. In some embodiments, a signal of the one or more first signals 510 is indicative of one or more instructions.

In some embodiments, the system 10 of the facility equipment 502 at least one of halts operation, removes or replaces the pellicle assembly and/or mask assembly, or performs another operation in response to receiving a signal (of the one or more first signals 510) indicating that the pellicle assembly is degraded. In some embodiments, the one or more first signals 510 comprise a signal transmitted to a machine, such as the system 10. In some embodiments, the signal instructs the machine to halt operation while the pellicle assembly is undergoing preventative maintenance. In some embodiments, the signal allocates one or more resources (e.g., manpower, a robot, one or more tools, the replacement component, etc.) to the system 10 to replace the pellicle assembly.

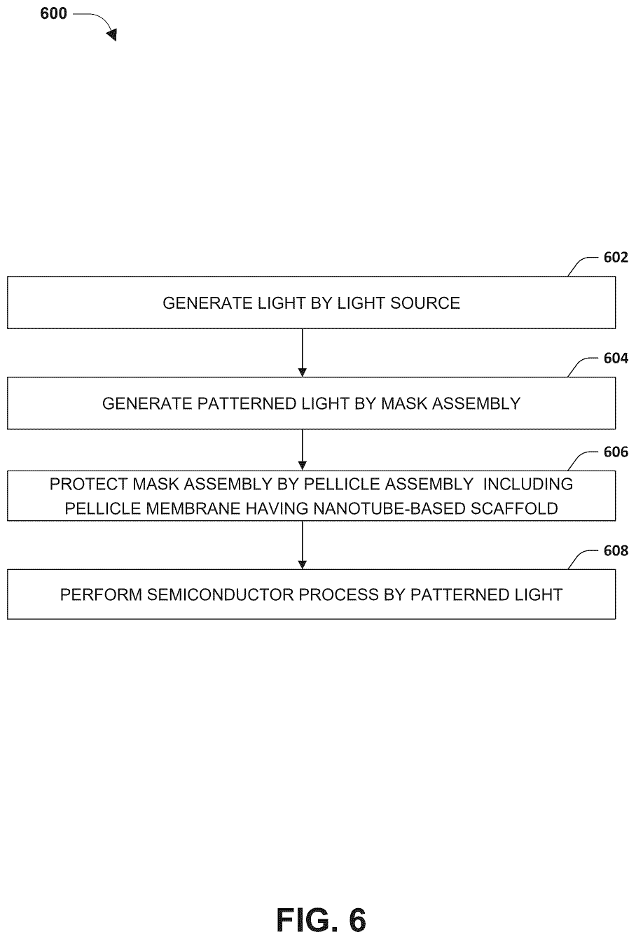

FIG. 6 is a flow diagram illustrating a method 600 of operating a system having a pellicle assembly, in accordance with some embodiments.

The method 600 is illustrated in FIG. 6 in accordance with some embodiments.

At 602, the method 600 includes generating light by a plasma of a light source of a semiconductor processing tool.

At 604, the method 600 includes generating patterned light by a mask assembly, the patterned light including the light reflected by a pattern of the mask assembly.

At 606, the method 600 includes, during generating the second light, protecting the mask assembly by a pellicle assembly including a pellicle membrane, the pellicle membrane including a nanotube-based scaffold structure having nanotubes bound together by a capping layer.

In some embodiments, protecting the mask assembly includes protecting the mask assembly by the pellicle assembly including the pellicle membrane having a first nanotube layer, a second nanotube layer on the first nanotube layer, and a melded capping layer that extends between nanotubes of the first and second nanotube layers. In some embodiments, the melded capping layer includes a metal oxide or a metal oxynitride. In some embodiments, the melded capping layer includes an oxide of ruthenium, niobium, aluminum, or molybdenum. In some embodiments, the melded capping layer includes an oxynitride of ruthenium, niobium, aluminum, or molybdenum. In some embodiments, the melded capping layer includes a dopant having concentration in a range of about 7 at % to about 10 at %. In some embodiments, the dopant includes vanadium or titanium.

At 608, the method 600 includes performing a semiconductor process on a semiconductor wafer by the patterned light.

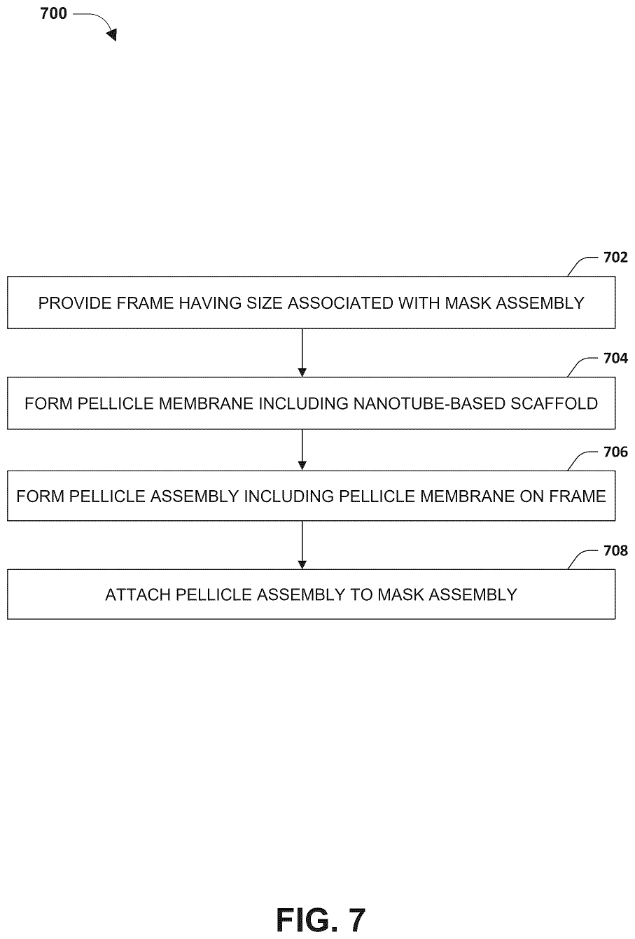

FIG. 7 is a flow diagram illustrating a method 700, in accordance with some embodiments.

The method 700 is illustrated in FIG. 7 in accordance with some embodiments.

At 702, the method 700 includes providing a frame having size associated with a mask assembly, the mask assembly being operable to reflect extreme ultraviolet (EUV) light according to a pattern of the mask assembly.

At 704, the method 700 includes forming a pellicle membrane including a nanotube-based scaffold structure having nanotubes bound together by a capping layer. In some embodiments, forming the pellicle membrane includes: forming a first nanotube layer; forming a first capping layer on the first nanotube layer; forming a second nanotube layer on the first capping layer; and forming a second capping layer on the second nanotube layer. In some embodiments, forming the pellicle membrane includes forming a third capping layer on the first nanotube layer. In some embodiments, forming the pellicle membrane includes melding the first and second capping layers by a thermal process. In some embodiments, forming the first capping layer includes forming a metal oxynitride by a deposition process. In some embodiments, forming the first capping layer includes flowing a dopant by the deposition process, the dopant including vanadium or titanium. In some embodiments, flowing the dopant includes flowing the dopant having concentration in a range of about 7 at % to about 10 at %. In some embodiments, forming the pellicle membrane includes forming the first nanotube layer on a sacrificial layer of the frame. In some embodiments, forming the pellicle membrane includes forming the pellicle membrane on a substrate including filter paper. In some embodiments, forming the pellicle assembly includes transferring the pellicle membrane to the frame. In some embodiments, forming the pellicle membrane on the substrate includes: forming a nanotube layer on the substrate by a first deposition process that deposits first nanotubes; and densifying the nanotube layer by a second deposition process that deposits second nanotubes on the first nanotubes. In some embodiments, forming the pellicle membrane on the substrate includes densifying the nanotube layer including the first and second nanotubes by applying pressure to the nanotube layer by flowing gas from opposite sides of the nanotube layer.

At 706, the method 700 includes forming a pellicle assembly including the pellicle membrane positioned on the frame.

At 708, the method 700 includes attaching the pellicle assembly to the mask assembly.

At 710, the method 700 includes, in response to the filter assembly not being degraded, performing a semiconductor process on a semiconductor wafer by the semiconductor processing tool.

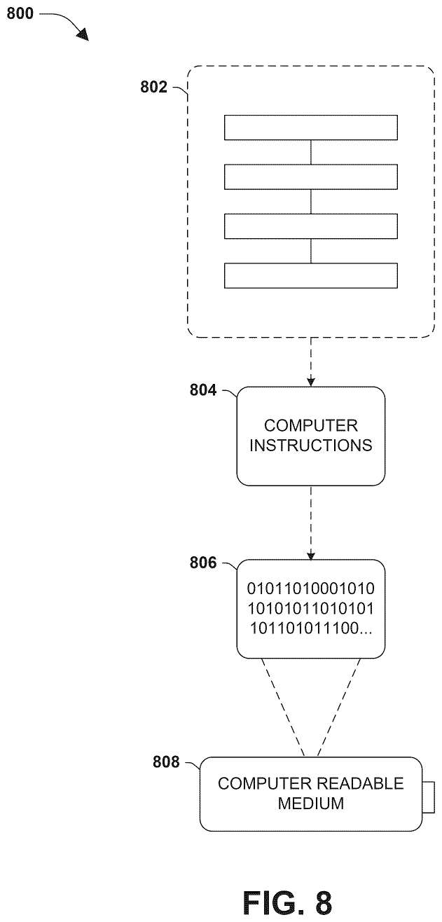

FIG. 8 illustrates an example computer-readable medium wherein processor-executable instructions configured to embody one or more of the provisions set forth herein may be comprised, according to some embodiments.

One or more embodiments involve a computer-readable medium comprising processor-executable instructions configured to implement one or more of the techniques presented herein. An exemplary computer-readable medium is illustrated in FIG. 8, wherein the embodiment 800 comprises a computer-readable medium 808 (e.g., a CD-R, DVD-R, flash drive, a platter of a hard disk drive, etc.), on which is encoded computer-readable data 806. This computer-readable data 806 in turn comprises a set of processor-executable computer instructions 804 configured to implement one or more of the principles set forth herein when executed by a processor. In some embodiments 800, the processor-executable computer instructions 804 are configured to implement a method 802, such as at least some of the aforementioned method(s) when executed by a processor. In some embodiments, the processor-executable computer instructions 804 are configured to implement a system, such as at least some of the one or more aforementioned system(s) when executed by a processor. Many such computer-readable media may be devised by those of ordinary skill in the art that are configured to operate in accordance with the techniques presented herein.

In some embodiments, a method is provided. The method includes: generating light by a plasma of a light source of a semiconductor processing tool; generating patterned light by a mask assembly, the patterned light including the light reflected by a pattern of the mask assembly; during generating the patterned light, protecting the mask assembly by a pellicle assembly including a pellicle membrane, the pellicle membrane including a nanotube-based scaffold structure having nanotubes bound together by a capping layer; and performing a semiconductor process on a semiconductor wafer by the patterned light.

In some embodiments, a method is provided. The method includes: providing a frame having size associated with a mask assembly, the mask assembly being operable to reflect extreme ultraviolet (EUV) light according to a pattern of the mask assembly; forming a pellicle membrane including a nanotube-based scaffold structure having nanotubes bound together by a capping layer; forming a pellicle assembly including the pellicle membrane positioned on the frame; and attaching the pellicle assembly to the mask assembly.

In some embodiments, a system is provided. The system includes: a light source operable to generate plasma that emits light in an extreme ultraviolet (EUV) spectrum; a collector mirror; a wafer stage, an optical path being defined from the light source, to the collector mirror, to the wafer stage; a mask stage positioned along the optical path between the collector mirror and the wafer stage; and a mask assembly positioned on the mask stage. The mask assembly includes: a frame; and a pellicle membrane positioned on the frame. The pellicle membrane includes: a first nanotube layer; a second nanotube layer on the first nanotube layer; and a capping layer. Nanotubes of the first and second nanotube layers are embedded in the capping layer.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A method, comprising:
generating light by a plasma of a light source of a semiconductor processing tool;
generating patterned light by a mask assembly, the patterned light including the light reflected by a pattern of the mask assembly;
during generating the patterned light, protecting the mask assembly by a pellicle assembly including a pellicle membrane, the pellicle membrane including a nanotube-based scaffold structure having nanotubes bound together by a capping layer; and
performing a semiconductor process on a semiconductor wafer by the patterned light.

2. The method of claim 1, wherein protecting the mask assembly by the pellicle assembly includes:
protecting the mask assembly by the pellicle assembly including the pellicle membrane having a first nanotube layer, a second nanotube layer on the first nanotube layer, and a melded capping layer that extends between nanotubes of the first and second nanotube layers.

3. The method of claim 2, wherein protecting the mask assembly by the pellicle assembly includes:
protecting the mask assembly by the pellicle assembly including the pellicle membrane having the melded capping layer that includes a metal oxide or a metal oxynitride.

4. The method of claim 3, wherein protecting the mask assembly by the pellicle assembly includes:
protecting the mask assembly by the pellicle assembly including the pellicle membrane having the melded capping layer that includes:
an oxide of ruthenium, niobium, aluminum or molybdenum; or
an oxynitride of ruthenium, niobium, aluminum, or molybdenum.

5. The method of claim 4, wherein protecting the mask assembly by the pellicle assembly includes:
protecting the mask assembly by the pellicle assembly including the pellicle membrane having the melded capping layer that includes a dopant having concentration in a range of about 7 at % to about 10 at %.

6. The method of claim 5, wherein protecting the mask assembly by the pellicle assembly includes:
protecting the mask assembly by the pellicle assembly including the pellicle membrane having the melded capping layer that includes the dopant including vanadium or titanium.

7. A method, comprising:
providing a frame having size associated with a mask assembly, the mask assembly being operable to reflect extreme ultraviolet (EUV) light according to a pattern of the mask assembly;
forming a pellicle membrane including a nanotube-based scaffold structure having nanotubes bound together by a capping layer;
forming a pellicle assembly including the pellicle membrane positioned on the frame; and
attaching the pellicle assembly to the mask assembly.

8. The method of claim 7, wherein forming the pellicle membrane includes:
forming a first nanotube layer;
forming a first capping layer on the first nanotube layer;
forming a second nanotube layer on the first capping layer; and
forming a second capping layer on the second nanotube layer.

9. The method of claim 8, wherein forming the pellicle membrane includes:
forming a third capping layer on the first nanotube layer.

10. The method of claim 8, wherein forming the pellicle membrane includes:
melding the first capping layer to the second capping layer by a thermal process.

11. The method of claim 8, wherein forming the first capping layer includes:
forming a metal oxynitride by a deposition process.

12. The method of claim 11, wherein forming the first capping layer includes:
flowing a dopant by the deposition process, the dopant including vanadium or titanium.

13. The method of claim 12, wherein flowing the dopant includes:
flowing the dopant having concentration in a range of about 7 at % to about 10 at %.

14. The method of claim 8, wherein forming the pellicle membrane includes:
forming the first nanotube layer on a sacrificial layer of the frame.

15. The method of claim 7, wherein:
forming the pellicle membrane includes forming the pellicle membrane on a substrate including filter paper; and
forming the pellicle assembly includes transferring the pellicle membrane to the frame.

16. The method of claim 15, wherein forming the pellicle membrane on the substrate includes:
forming a nanotube layer on the substrate by a first deposition process that deposits first nanotubes; and
densifying the nanotube layer by a second deposition process that deposits second nanotubes on the first nanotubes.

17. The method of claim 16, wherein forming the pellicle membrane on the substrate includes:
densifying the nanotube layer including the first nanotubes and the second nanotubes by applying pressure to the nanotube layer by flowing gas from opposite sides of the nanotube layer.

18. A system, comprising:
a light source operable to generate plasma that emits light in an extreme ultraviolet (EUV) spectrum;
a collector mirror;
a wafer stage, an optical path being defined from the light source, to the collector mirror, to the wafer stage;
a mask stage positioned along the optical path between the collector mirror and the wafer stage; and
a mask assembly positioned on the mask stage, the mask assembly including:
a frame; and
a pellicle membrane positioned on the frame, the pellicle membrane including:
a first nanotube layer;
a second nanotube layer on the first nanotube layer; and
a capping layer, nanotubes of the first and second nanotube layers being embedded in the capping layer.

19. The system of claim 18, wherein grain size of the capping layer is in a range of about 1 nanometer (nm) to about 10 nm.

20. The system of claim 18, wherein the capping layer includes vanadium oxynitride, titanium oxynitride or both.
